(19) United States
(12) Patent Application Publication
(10) Pub. No.: US 2008/0012058 A1
(43) Pub. Date: Jan. 17, 2008

(54) Semiconductor device and method of manufacturing same

(75) Inventor: Hidekazu Nobuto, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: ELPIDA MEMORY, INC

(21) Appl. No.: 11/605,304

(22) Filed: Nov. 29, 2006

(30) Foreign Application Priority Data
Jul. 12, 2006 (JP) 2006-192226

(51) Int. Cl. H01L 29/94; H01L 21/8242

(52) U.S. Cl. 257/306; 438/253; 257/E27.086

(57) ABSTRACT

The present invention provides a semiconductor device which can reduce consumption electric power even though high integration and technologies such as microfabrication further proceeds in future and a method of manufacturing the same. The present invention comprises a semiconductor substrate, a transistor formed on said semiconductor substrate, a first electric element electrically connected to said transistor, and a second electric element electrically connected to said first electric element, wherein said first electric element and said second electric element are connected in such way that at least two planes parallel with said semiconductor substrate surface and passing through both of said first electric element and said second electric element.

### BACKGROUND OF THE INVENTION

1. Field of the Invention

The present invention relates to a semiconductor device of DRAM (Dynamic Random Access Memory) and the like, and a method for manufacturing same, more particularly a semiconductor device comprising electric elements such as a capacitance element, bit contact, etc. and a manufacturing the same.

2. Description of the Related Art

Generally a memory cell included in DRAM and a line consists of electric elements such as a transistor for memory cells, a cell contact, a capacitance element, abit contact, abit line (Japanese Patent Application publication 2005-72176).

FIG. 53 is a schematic sectional diagram explaining the memory cells in the conventional DRAM.

As shown in FIG. 53, the MOS field-effect transistor 100 formed on the semiconductor substrate 1 such as semiconductor device silicon substrate. This MOS field-effect transistor 100 functions as a transistor for memory cells.

A cell contact 2 electrically connected to said MOS field-effect transistor 100 is formed on the upper layer said MOS field-effect transistor 100.

A capacitance contact 3 electrically connected to said cell contact 2 if formed on the upper layer of said cell contact 2.

A capacitance element 400 electrically connected to said capacitance contact 3 is formed on the upper layer of said capacitance contact 3.

The side face of said cell contact 2, the side face of said capacitance contact 3, the side face of said capacitance element 400 are respectively insulated by first interlayer insulation film 5, the second interlayer insulation film 6 and the third interlayer insulator 7. These interlayer insulators are formed of silicon oxide and the like.

Said capacitance element 400 comprise an upper electrode 8 formed of TiN, a capacitance film 9 formed of hafnium oxide and aluminum oxide, and a lower electrode 10 formed of TiN.

Said cell contact 2 and said capacitance contact 3 are formed polysilicon containing impurity.

And a TiSi layer 11 is formed on the upper end surface of said capacitance contact 3.

While, as shown in FIG. 53, a cell contact 40 electrically connected to said MOS field-effect transistor 100 is formed on the upper layer of said MOS field-effect transistor 100.

A bit contact 41 electrically connected to said cell contact 40 is formed on the upper layer of said cell contact 40.

A bit line 43 electrically connected to said bit contact 41 is formed on the upper layer of said bit contact 41.

A side face of said cell contact 40, side of a said face of said bit contact 41, and a side face of said bit line 43 are insulated with first interlayer insulation film 5 and second interlayer insulation film 6 respectively.

Further, a WSi₂ layer 42 is formed on an upper end face of said cell contact 40.

FIG. 54 is a schematic sectional diagram showing said second interlayer insulation film 6 and said third interlayer insulation film 7 crossed with plane parallel with said semiconductor substrate 1 in view of normal direction with said semiconductor substrate 1.

A circular shape 51 expresses the upper end face of said capacitance contact 3, and an oval shape 50 expresses the lower end face of said capacitance element 400.

Thus said capacitance contact 3 and said capacitance element 400 are electrically connected.

Said cell contact 40 and said bit contact 41 are same.

However, with the recent technical progress of high integration and microfabrication of semiconductor devices such as DRAM, the contact area between said capacitance contact 3 and said capacitance element 400, and the contact area between said cell contact 40 and said bit contact 41 tend to be reduced.

When said contact areas become reduced, the resistance against electric current between said capacitance contact 3 and said capacitance element 400 and the resistance against electric current between said cell contact 40 and said bit contact 41 become increased and as a result electric power consumption of obtained semiconductor devices of DRAM becomes increased. There was such problem.

Further, as shown in FIG. 54 explained above, some cases are that the upper end 51 of said capacitance contact 3 and the lower end 50 of said capacitance element 400 are not superimposed to each other as designed, thereby for example as shown by FIG. 55, the upper end 51 of said capacitance contact 3 and the lower end 50 of said capacitance 400 are not connected without corresponding to each other.

In these cases, the contact area between said capacitance contact 3 and said capacitance element 400 becomes smaller, thereby obtained consumption electric power becomes larger.

### BRIEF SUMMARY OF THE INVENTION

An object of the present invention is to provide a semiconductor device that can keep the electric power consumption low even if technologies such as high integration and microbabrication proceed in future, and a method of manufacturing the same.

That means, the present invention provides
[1] a semiconductor device comprising:

a semiconductor substrate;

a transistor formed on the said semiconductor substrate;

a first electric element electrically connected to said transistor; and

a second electric element electrically connected to said first electric element;

wherein said first electric element and said second electric element are connected in such say that at least two planes are parallel to said semiconductor substrate surface and passing through both of said first electric element and said second electric element.

### And the present invention provides

[2] a semiconductor device comprising:

a semiconductor substrate;

a transistor formed on said semiconductor substrate;

a cell contact electrically connected to said transistor;

a capacitance contact electrically connected to said cell contact; and

a capacitance element electrically connected to said capacitance contact,

wherein said capacitance contact and said capacitance element are connected in such way that at least two planes are parallel to said semiconductor substrate surface and passing through both of said capacitance contact and said capacitance element.

And the present invention provides
[3] a semiconductor device according to the above [2], wherein a connection surface of said capacitance contact and said capacitance element comprises a connection portion in parallel direction with said semiconductor substrate surface and a connection portion in perpendicular direction with said semiconductor substrate surface.

And the present invention provides
[4] a semiconductor-device according to any one of the above [2] to [3], wherein said capacitance contact comprises at least one step (A) at end portion connected to said capacitance element, said capacitance element is assembled in such way that said capacitance element is electrically connected to at least one portion of said step (A).

And the present invention provides
[5] a semiconductor device according to any one of the above [2] to [4], wherein said capacitance element comprises a lower electrode, a capacitance film and an upper electrode.

And the present invention provides
[6] a method of manufacturing a semiconductor device in which a capacitance element electrically connected to a transistor is formed on an upper layer of said transistor formed on a semiconductor substrate comprising steps of:

(a) forming a transistor on the semiconductor substrate;

(b) forming a first interlayer insulation film covering said transistor,

(c) forming a cell contact electrically connected to said transistor in said first interlayer insulation film,

(d) forming a second interlayer insulation film covering said first interlayer insulation film and said cell contact,

(e) forming a capacitance contact electrically connected to said cell contact in said second interlayer insulation film,

(f) forming a third interlayer insulation film covering said second interlayer insulation film and said capacitance contact,

(g) etching at least one selected from a group of said capacitance contact, said second interlayer insulation film and said third interlayer insulation film in perpendicular direction of said semiconductor substrate, and

(h) forming a capacitance element comprising a portion electrically connected in parallel direction with said semiconductor substrate, and a portion electrically connected to said semiconductor substrate in perpendicular direction, with respect to said capacitance contact.

And the present invention provides
[7] a method of manufacturing a semiconductor device according to the above [6], wherein the step (h) of forming said capacitance element comprises a step of forming a lower electrode, a capacitance film and an upper electrode.

And the present invention provides
[8] a semiconductor device comprising:

a semiconductor substrate;

a transistor formed on said semiconductor substrate;

a cell contact electrically connected to said transistor;

a bit contact electrically connected to said cell contact; and

a bit line electrically connected to said bit contact;

wherein said cell contact and said bit contact are connected in such way that at least two planes are parallel with said semiconductor substrate surface and passing through both of said cell contact and said bit contact.

The present invention provides
[9] a semiconductor device according to the above [8], wherein a connection surface between said cell contact and said bit contact has a connection portion parallel with said semiconductor substrate surface, and a connection portion perpendicular with said semiconductor substrate surface.

The present invention provides
[10] a semiconductor device according to any one of the above [8] to [9], wherein said cell contact comprises at least one step (A) at end portion connected to said bit contact, and said bit contact is assembled so as to be electrically connected to at least one portion.

The present invention provides
[11] a method of manufacturing a semiconductor device in which a bit line electrically connected to a transistor is formed on an upper layer of said transistor formed on a semiconductor substrate comprising steps of:

(a) forming a transistor on the semiconductor substrate;

(b) forming a first interlayer insulation film covering said transistor,

(c) forming a cell contact electrically connected to said transistor in said first interlayer insulation film,

(d) forming a second interlayer insulation film covering said first interlayer insulation film and said cell contact,

(e) etching at least one selected from a group of said cell contact, said first interlayer insulation film and said second interlayer insulation film in perpendicular direction of said semiconductor substrate,

(f) forming a bit contact comprising a portion electrically connected in parallel direction with said semiconductor substrate, and a portion electrically connected to said semiconductor substrate in perpendicular direction, with respect to said cell contact, and

(g) forming a bit line electrically connected to said bit contact.

With the present invention, provided area semiconductor device that can keep the electric power consumption low even if technologies such as high integration and microfabrication proceed in future, and a method of manufacturing the same.

### BRIEF DESCRIPTION OF THE DRAWINGS

The above and other objects and features of the invention will appear more fully hereinafter from a consideration of the following description taken in connection with the accompanying drawing wherein one example is illustrated by way of example, in which;

FIG. 1 is a schematic sectional diagram explaining a first embodiment related to a semiconductor device of the present invention;

FIG. 2 is a schematic sectional diagram explaining a second embodiment related to a semiconductor device of the present invention;

FIG. 3 is an enlarged schematic sectional diagram explaining a connection portion between said capacitance contact and said capacitance element;

FIG. 4 is a schematic sectional diagram showing a modified example of a connection portion between the capacitance contact and the capacitance element;

FIG. 5 is a schematic sectional diagram showing a modified example of a connection portion between the capacitance contact and the capacitance element;

FIG. 6 is a schematic sectional diagram explaining each portion of the capacitance contact and the capacitance element;

FIG. 7 is a schematic sectional diagram explaining each portion of the capacitance contact and the capacitance element;

FIG. 8 is a schematic sectional diagram explaining a third embodiment related to a semiconductor device of the present invention;

FIG. 9 is a schematic sectional diagram explaining a forth embodiment related to a semiconductor device of the present invention;

FIG. 10 is a schematic sectional diagram explaining a fifth embodiment related to a semiconductor device of the present invention;

FIG. 11 is a schematic sectional diagram explaining a sixth embodiment related to a semiconductor device of the present invention;

FIG. 12 is a schematic sectional diagram explaining a modified example of a connection portion between a cell contact and a bit contact;

FIG. 13 is an schematic sectional diagram explaining a modified example of a connection portion between a cell contact and a bit contact;

FIG. 14 is a schematic sectional diagram explaining a sixth embodiment related to a semiconductor device of the present invention;

FIG. 15 is a schematic sectional diagram explaining a seventh embodiment related to a semiconductor device of the present invention;

FIG. 16 is as schematic sectional diagram explaining each portion of a cell contact and a bit contact;

FIG. 17 is a schematic sectional diagram explaining an eighth embodiment related to a semiconductor device of the present invention;

FIG. 18 is a schematic sectional diagram explaining a ninth embodiment related to a semiconductor device of the present invention;

FIG. 19 is a schematic sectional diagram explaining a process of forming a MOS field-effect transistor on the semiconductor substrate;

FIG. 20 is a schematic sectional diagram explaining a process of forming a cell contact;

FIG. 21 is a schematic sectional diagram explaining a process of forming a cell contact;

FIG. 22 is a schematic sectional diagram explaining a process of forming a cell contact;

FIG. 23 is a schematic sectional diagram explaining a process of forming a capacitance contact;

FIG. 24 is a schematic sectional diagram explaining a process of forming a capacitance contact;

FIG. 25 is a schematic sectional diagram explaining a process of forming a capacitance contact;

FIG. 26 is a schematic sectional diagram explaining a process of etching a capacitance contact, a second interlayer insulation film and a third interlayer insulation film in a normal direction with the semiconductor substrate;

FIG. 27 is a schematic sectional diagram explaining a process of forming a contact hole of a first embodiment;

FIG. 28 is a schematic sectional diagram explaining a process of forming a contact hole of a first embodiment;

FIG. 29 is a schematic sectional diagram explaining a process of forming a contact hole of a first embodiment;

FIG. 30 is a schematic sectional diagram explaining a process of forming a contact hole of a first embodiment.

FIG. 31 is a schematic sectional diagram explaining a process of forming a contact hole, a modified example of the contact hole of the first embodiment;

FIG. 32 is a schematic sectional diagram explaining a process of forming a contact hole, a modified example of the contact hole of the first embodiment;

FIG. 33 is a schematic sectional diagram explaining a process of forming a contact hole, a modified example of the contact hole of the first embodiment;

FIG. 34 is a schematic sectional diagram explaining a process of forming a contact hole, a modified example of the contact hole of the first embodiment;

FIG. 35 is a schematic sectional diagram explaining a process of forming a contact hole, a modified example of the contact hole of the first embodiment;

FIG. 36 is a schematic sectional diagram explaining a process of forming a contact hole, a modified example of the contact hole of the first embodiment;

FIG. 37 is a schematic sectional diagram explaining a process of forming a contact hole of a third embodiment;

FIG. 38 is a schematic sectional diagram explaining a process of forming a contact hole of a third embodiment;

FIG. 39 is a schematic sectional diagram explaining a process of forming a contact hole of a fourth embodiment;

FIG. 40 is a schematic sectional diagram explaining a process of forming a contact hole of a fourth embodiment;

FIG. 41 is a schematic sectional diagram explaining a process of forming a contact hole of a fourth embodiment;

FIG. 42 is a schematic sectional diagram explaining a process of forming a contact hole of a fourth embodiment;

FIG. 43 is a schematic sectional diagram explaining a process of forming a contact hole of a fourth embodiment;

FIG. 44 is a schematic sectional diagram explaining a process of forming a contact hole of a fifth embodiment;

FIG. 45 is a schematic sectional diagram explaining a process of forming a contact hole of a fifth embodiment;

FIG. 46 is a schematic sectional diagram explaining a process of forming a contact hole of a fifth embodiment;

FIG. 47 is a schematic sectional diagram explaining a process of forming a capacitance element of a first embodiment;

FIG. 48 is a schematic sectional diagram explaining a process of forming a capacitance element of a first embodiment;

FIG. 49 is a schematic sectional diagram explaining a process of forming a capacitance element of a first embodiment;

FIG. 50 is a schematic sectional diagram explaining a process of forming contact cell, a bit cell and a bit line of sixth embodiment;

FIG. 51 is a schematic sectional diagram explaining a process of forming contact cell, a bit cell and a bit line of sixth embodiment;

FIG. 52 is a schematic sectional diagram explaining a process of forming contact cell, a bit cell and a bit line of sixth embodiment;

FIG. 53 is a schematic sectional diagram showing a memory cell included in the conventional DRAM;

FIG. 54 is a schematic sectional diagram showing a connection surface between a first electric element and a second electric element; and

FIG. 55 is a schematic sectional diagram showing a connection surface between a first electric element and a second electric element.

### DETAILED DESCRIPTION OF THE INVENTION

Embodiments of the present invention will be described in detail with reference to drawings.

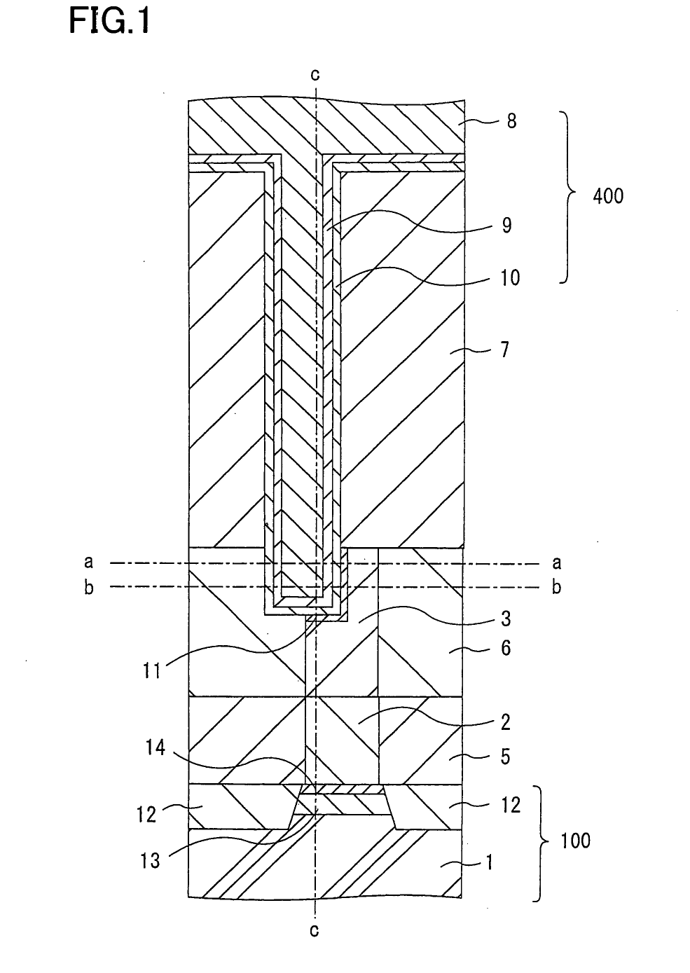

FIG. 1 is a schematic sectional diagram of a first embodiment related to a semiconductor device of the present invention.

A semiconductor device of the present invention has memorial cells. As shown in FIG. 1, a semiconductor substrate 1 of semiconductor silicon and the like is provided with an element separation insulation film 12, and cell regions are individually divided in memory cell regions. A source drain region 13 is formed by introducing impurities into said semiconductor substrate 1 divided by this element separation insulation film 12. And a cobalt silicide layer 14 is provided on the upper end of said source drain region 13.

Said source drain region 13 is provided with a gate electrode which is not especially shown.

Like this MOS field-effect transistor 100 is formed in the semiconductor substrate 1 and functions as a transistor for memorial.

A cell contact 2 electrically connected to said MOS field-effect transistor 100 through said cobalt silicide layer 14 is formed on said MOS field-effect transistor 100.

A capacitance contact 3 electrically connected to said cell contact 2 is formed on said cell contact 2.

Said capacitance contact 3 is formed of polysilicon containing impurity element, and a TiSi layer 11 is formed on the connection face with said capacitance element 400.

Said capacitance element 400 electrically connected to said capacitance contact 3 is formed on a part of the side face of this capacitance contact 3.

Said capacitance element 400 comprises an upper electrode 8 formed of TiN, a capacitance film 9 formed of hafnium oxide and aluminum oxide, and a lower electrode 10 formed of TiN.

A side face of said cell contact 2, a side face of said capacitance contact 3, and a side face of said capacitance element 400 are insulated with each other respectively by a first interlayer insulation film 5, a second interlayer insulation film 6, and a third interlayer insulation film 7.

A part of the side face and a part of the bottom face of said capacitance element 400 are insulated by said second interlayer insulation film 6.

These interlayer insulation films are each formed of silicon oxide and the like.

In said first embodiment as shown in FIG. 1, there exist at least two planes parallel to said semiconductor substrate surface and passing through both of said capacitance contact 3 as a first electric element and said capacitance element 400 as a second electric element.

Specifically, there exist at least two planes parallel to said semiconductor substrate surface and passing through respectively a dot-dash line a-a, and a dot-dash line b-b in FIG. 1.

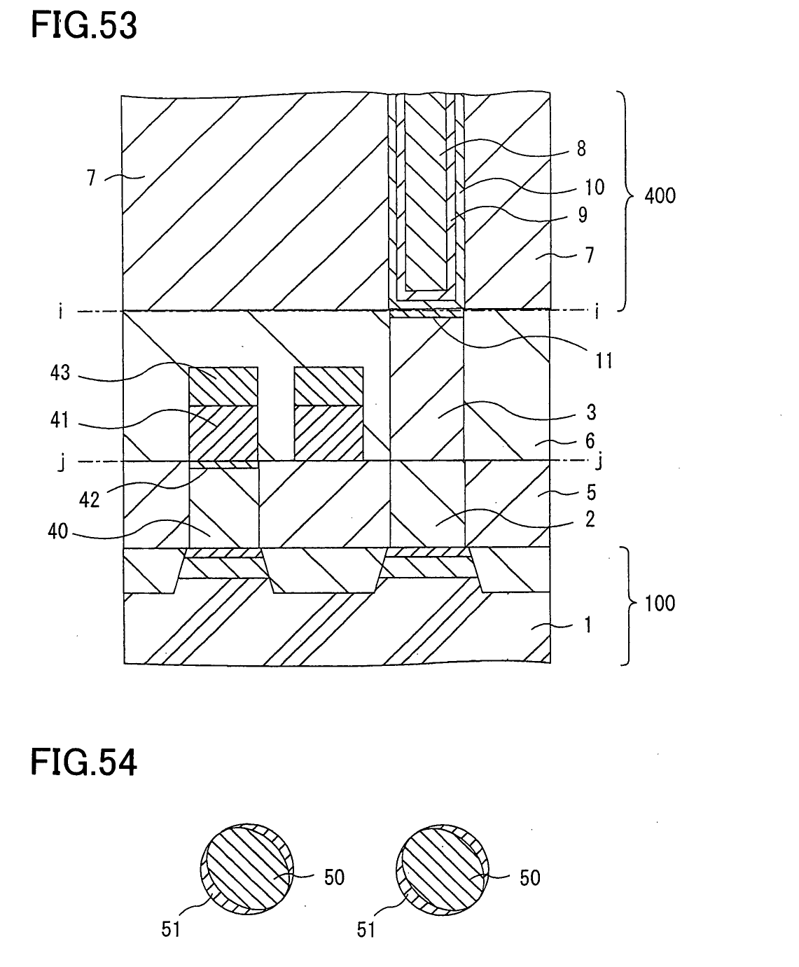

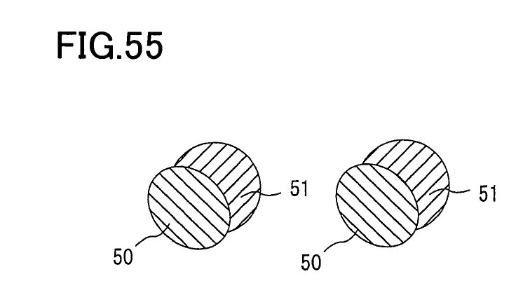

As shown in FIG. 53 which was explained before, a plane parallel to said semiconductor substrate surface and passing through both of said capacitance contact 3 and said capacitance element 400 is one of planes passing through a dot-dash line i-i in FIG. 53.

In the case of said first embodiment as shown in FIG. 1, there exists at least one plane perpendicular to said semiconductor substrate surface and passing through both of said capacitance contact 3 and said capacitance element 400.

Specifically, there exists one plane perpendicular to said semiconductor substrate surface and passing a dot-dash line c-c in FIG. 1.

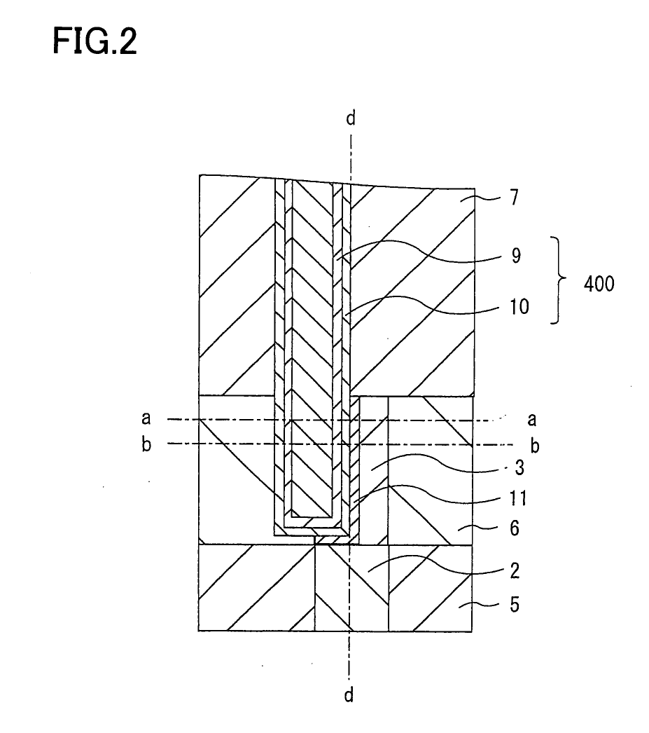

A second embodiment shown in FIG. 2 is a modified example of the first embodiment.

Here FIG. 2 is a schematic sectional diagram explaining a second embodiment related to the semiconductor device of the first invention and enlarged views of said capacitance element 400, said capacitance contact 3 and said cell contact 2.

As shown in FIG. 2, the bottom face of said capacitance element 400 may be arranged near the bottom of said capacitance contact 3.

In this case, in said second embodiment as shown in FIG. 2, there exist at least two or more planes parallel to said semiconductor substrate surface and passing through both of said capacitance contact 3 as a first electric element and said capacitance element 400 as a second electric element.

Specifically, at least two planes parallel to said semiconductor substrate surface and passing through respectively a dot-dash line a-a, and a dot-dash line b-b in FIG. 2.

In the case of said second embodiment, there exists at least one plane perpendicular to said semi conductor substrate 1 surface passing both of said capacitance contact 3 and said capacitance element 400.

Specifically, there exists one plane perpendicular to said semiconductor substrate 1 surface and passing through a dot-dash line d-d in FIG. 2.

The bottom of said capacitance element 400 may be arranged so as to correspond the bottom of said capacitance contact 3. Further the bottom of said capacitance element 400 may be arranged so as to reach said cell contact 2 (not shown).

The bottom of said capacitance element 400 is preferably located in the scope from ½ to ¾ of height of said capacitance contact on basis of the bottom face of said capacitance contact 3.

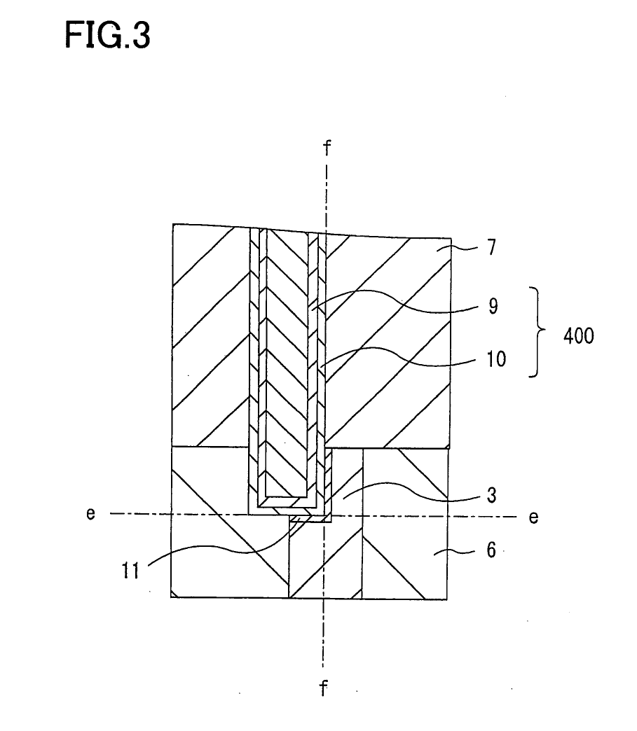

FIG. 3 is an enlarged schematic sectional diagram explaining the connection portion between said capacitance contact 3 and said capacitance element 400 in the semiconductor device shown in FIG. 1 previously described.

The connection surface between said capacitance contact 3 and said capacitance element 400 includes a connection portion parallel to said semiconductor substrate 1 surface (a dot-dash line e-e) and the connection portion perpendicular to said semiconductor substrate 1 surface (a dot-dash line f-f).

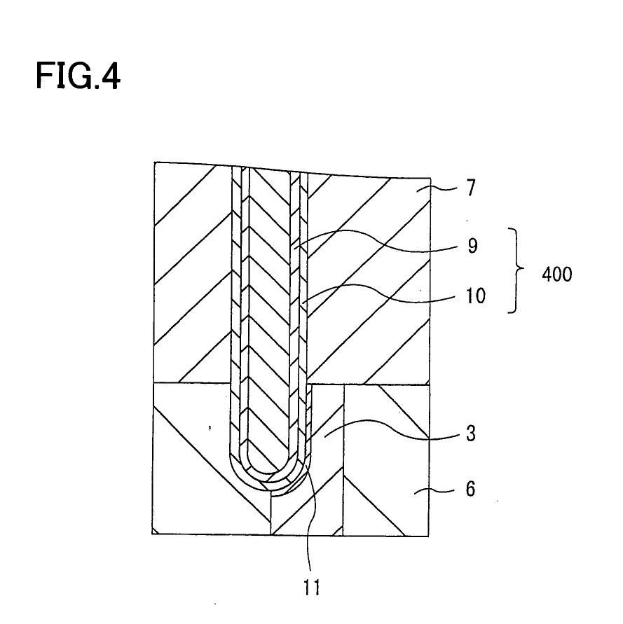

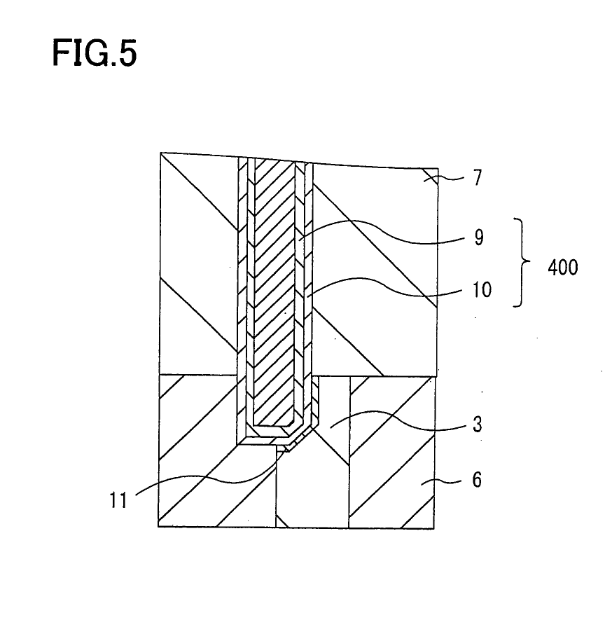

The connection surface between said capacitance contact 3 and said capacitance element 400 may include a connection portion parallel to said semiconductor substrate 1 surface and the connection portion perpendicular to said semiconductor substrate 1 surface as a whole. As shown in FIG. 4, the connection surface between said capacitance contact 3 and said capacitance element 400 may include a curved surface. As shown in FIG. 5, the connection surface between said capacitance contact 3 and said capacitance element 400 may have an oblique plane with respect of the semiconductor substrate 1 surface.

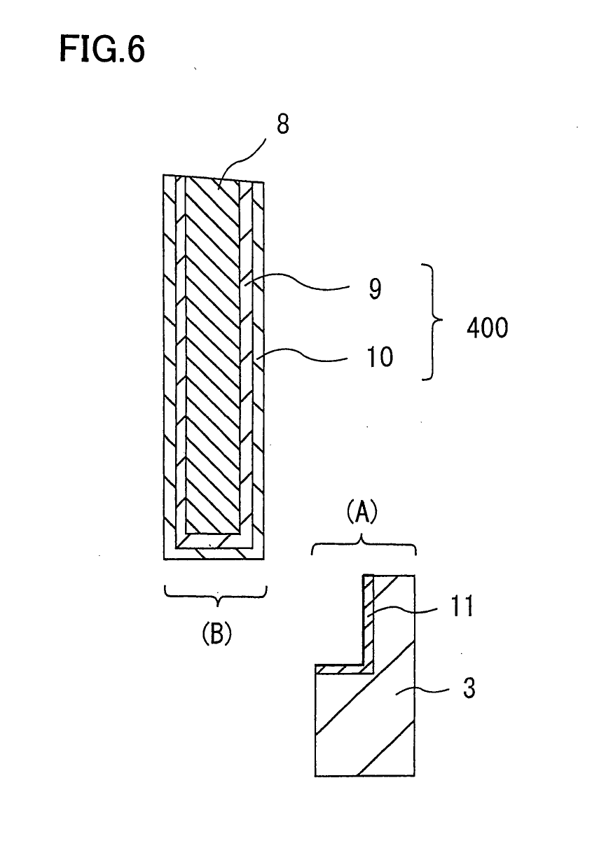

FIG. 6 is a schematic sectional diagram explaining portions of said capacitance contact 3 and said capacitance element 40 shown in FIG. 3, respectively.

In the first embodiment of the semiconductor device of the present invention as shown in FIG. 6, said capacitance contact 3 has at least one step (A) at an end portion connected to said capacitance element 400. As shown in FIG. 3, at least one of these steps (A) is electrically connected to said capacitance element 400.

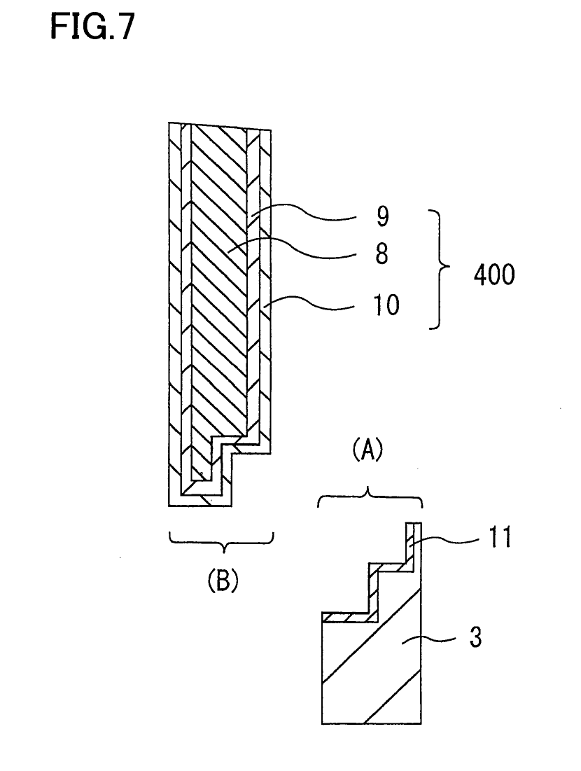

FIG. 7 is a schematic sectional diagram explaining a third embodiment related to the semiconductor device of the present invention and portions of said capacitance contact 3 and said capacitance element 400, respectively.

Said connection surface included in the semiconductor of the present invention is not limited to the example shown by FIG. 3. The connection surface with said capacitance element 400 may have at least one step (B) at end portion connected to said capacitance contact 3.

And said capacitance contact 3 has at least one step (A) at end portion connected to said capacitance element 400.

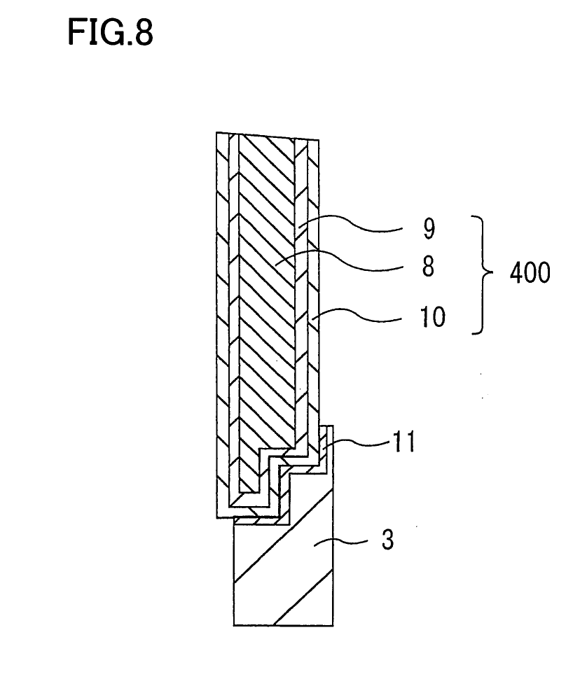

These steps (A) and (B) as shown in FIG. 8 are complimentarily assembled, thereby said capacitance contact 3 and said capacitance element 400 are electrically connected with each other.

As shown in FIG. 8, cross-sectional shapes of the connection surfaces of said capacitance contact 3 and said capacitance element 400, which are formed by assembling said steps (A) and (B) may have two or more steps respectively.

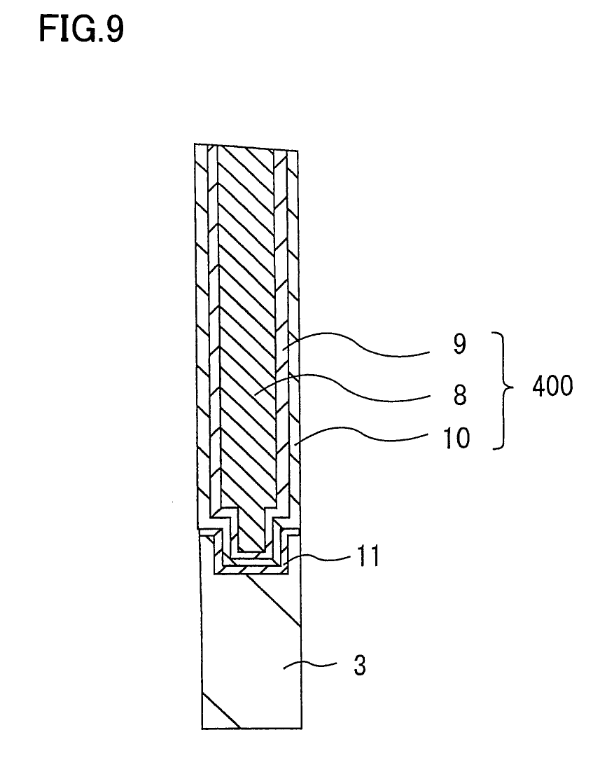

FIG. 9 is a schematic sectional diagram explaining a fourth embodiment related to the semiconductor device of the present invention and portions of said capacitance contact 3 and said capacitance element 400, respectively.

The cross-sectional shape of the connection surface between said capacitance contact 3 and said capacitance element 400 is not limited to the step shape exemplified by FIGS. 3, 8, etc. For example, as shown in FIG. 9, the cross-sectional shape of the connection surface between said capacitance contact 3 and said capacitance element 400, may be in shape of concave and convex which are assembled with each other.

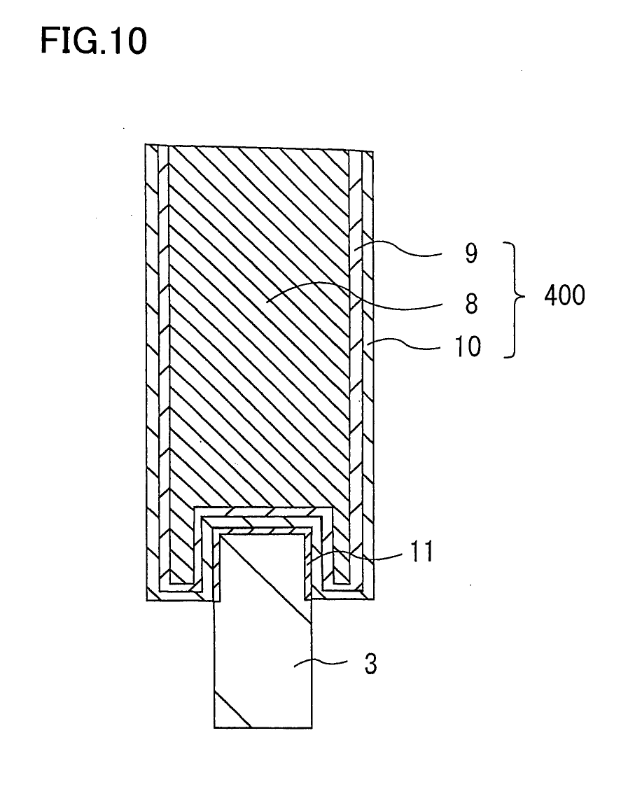

FIG. 10 is a schematic sectional diagram explaining a fifth embodiment related to the semiconductor device of the present invention and portions of said capacitance contact 3 and said capacitance element 400, respectively.

A relation of the connection surface between said capacitance contact 3 and said capacitance element 400 is conversed with that of the fourth embodiment. These surface cross-sectional shapes are formed by assembling concave-convex shapes with each other.

Next, different embodiments of the present invention will be described.

In the above mentioned embodiments of 1st to 5th, the capacitance contact is exemplified as said first electric element and the capacitance element is exemplified as said second electric element.

In the embodiments described next is a cell contact is exemplified as said first electric element and a bit contact is exemplified as said second electric element.

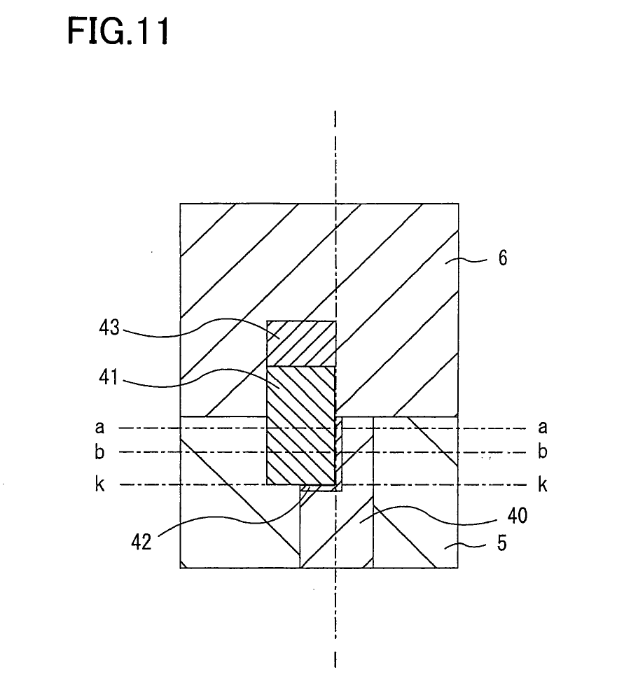

FIG. 11 is a schematic sectional diagram explaining a sixth embodiment related to the semiconductor device of the present invention and portions of said bit contact 41 and said cell contact 40, respectively.

On the upper surface of the above mentioned MOS field-effect transistor 100 is formed with the cell contact 40 electrically connected through said cobalt silicide layer (not shown).

Said cell contact 40 is formed of polysilicon containing impurity element, and WSi₂ layer 42 is formed on said bit contact 41.

Said bit contact 41 electrically connected to said cell contact 40 is formed on an upper layer and a part of a side face of said cell contact 40.

Said bit contact 41 is formed of metals including W. This bit contact 41 is provided with a bit line 43 formed of metals including W on the upper layer thereof.

A side face of said cell contact 40, a side face of said bit contact 41, and a side face of said bit line 43 are insulated with each other by a first interlayer insulation film 5, a second interlayer insulation film 6, and a second interlayer insulation film 6, respectively.

A part of the side face and a part of the bottom face of said bit contact 41 are insulated by said first interlayer insulation film 5.

These interlayer insulation films are each formed of silicon oxide.

In said sixth embodiment as shown in FIG. 11, there exist at least two planes parallel to said semiconductor substrate surface and passing through both of said cell contact 40 as a first electric element and said bit contact 41 as a second electric element.

Specifically, there exist at least two planes parallel to said semiconductor substrate surface and passing through respectively a dot-dash line a-a, and a dot-dash line b-b in FIG. 11.

Further, a connection surface between said cell contact 40 and said bit contact 41 includes a connection portion (a dot-dash line k-k) in direction of parallel to said semiconductor substrate 1 surface and a connection portion (a dot-dash line 1-1) in direction of perpendicular to said semiconductor substrate 1 surface.

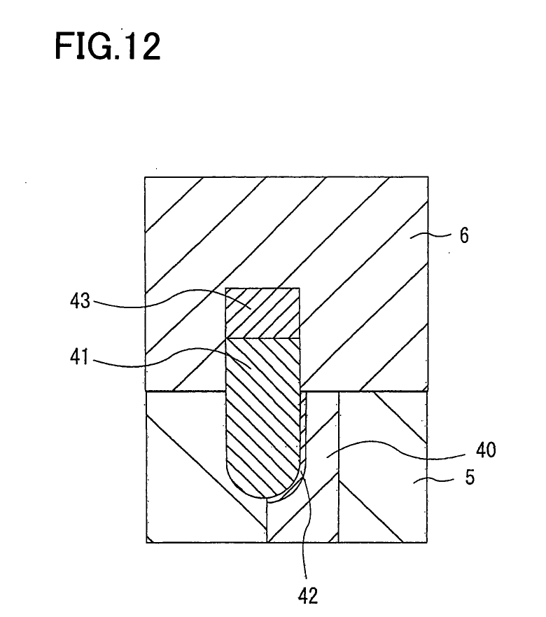

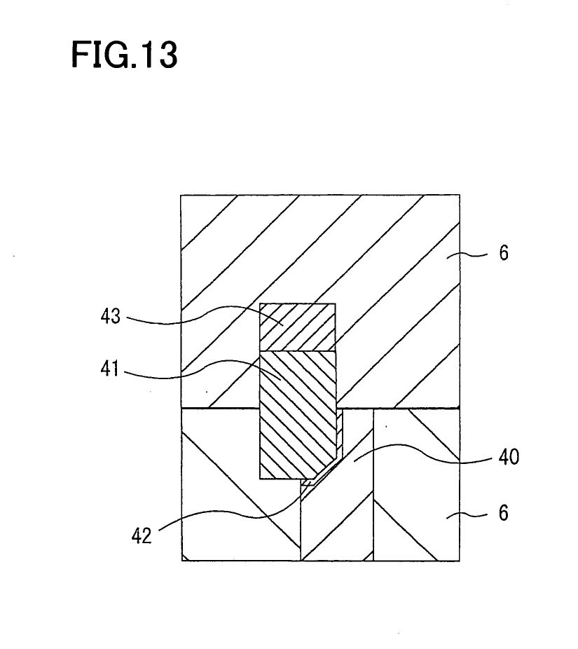

The connection surface between said cell contact 40 and said bit contact 40 may include a connection portion parallel to said semiconductor substrate 1 surface and the connection portion perpendicular to said semiconductor substrate 1 surface as a whole. As shown in FIG. 12, the connection surface between said cell contact 40 and said bit contact 41 may include a curved surface. As shown in FIG. 13, the connection surface between said cell contact 40 and said bit contact 41 may have an oblique plane with respect to said semiconductor substrate 1.

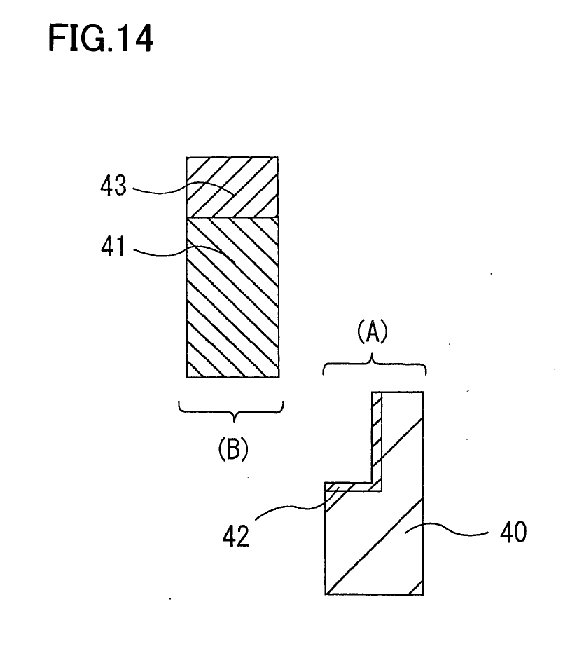

FIG. 14 is a schematic sectional diagram explaining a sixth embodiment related to the semiconductor device of the present invention and portions of cell contact 40, said bit contact 41 and said bit line 43, respectively.

In the sixth embodiment of the semiconductor device of the present invention, as shown in FIG. 14, said cell contact 40 has at least one step (A) at an end portion connected to said bit contact 41. As shown in FIG. 11, at least one of these steps (A) is electrically connected to said bit contact 41.

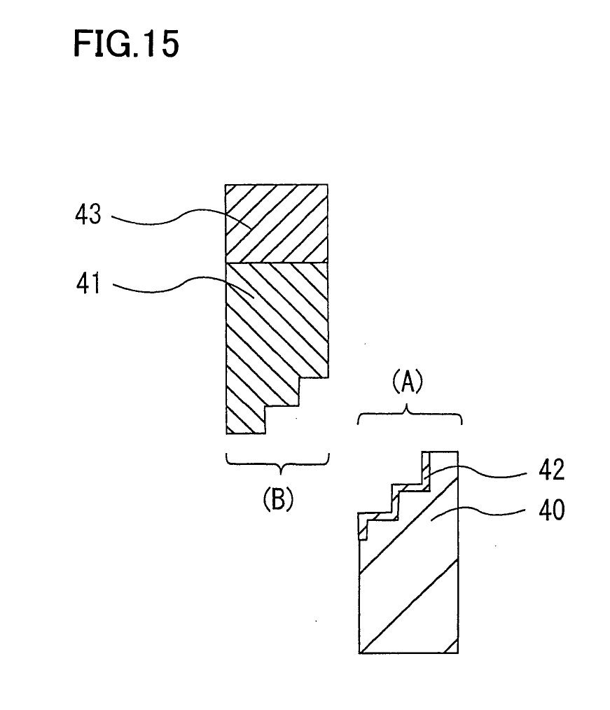

FIG. 15 is a schematic sectional diagram explaining a sixth embodiment related to the semiconductor device of the present invention and portions of cell contact 40, said bit contact 41 and said bit line 43, respectively.

Said connection surface included in the semiconductor of the present invention is not limited to the example shown by FIG. 11. The connection surface with said bit contact 41 may have step (B) at end portion connected to said cell contact 40.

And said cell contact 40 has at least one step (A) at end portion connected to said bit contact 41.

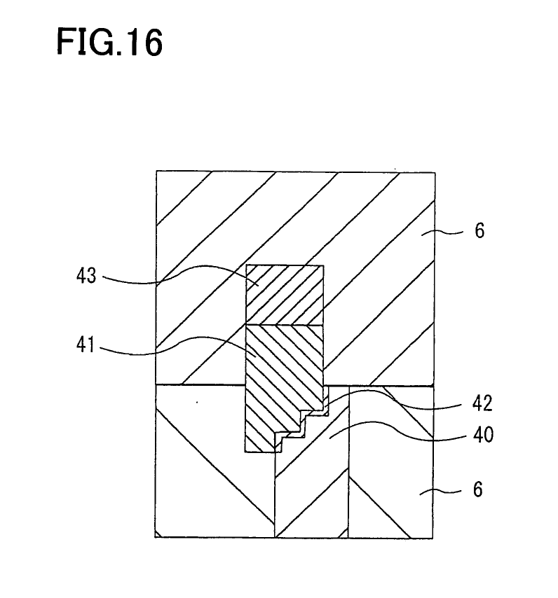

These steps (A) and (B) as shown in FIG. 16 are complimentarily assembled, thereby said cell contact 40 and said bit contact 41 are electrically connected with each other.

As shown in FIG. 16, cross-sectional shapes of the connection surfaces of said cell contact 40 and said bit contact 41 which are formed by assembling said steps (A) and (B) may have two or more steps respectively.

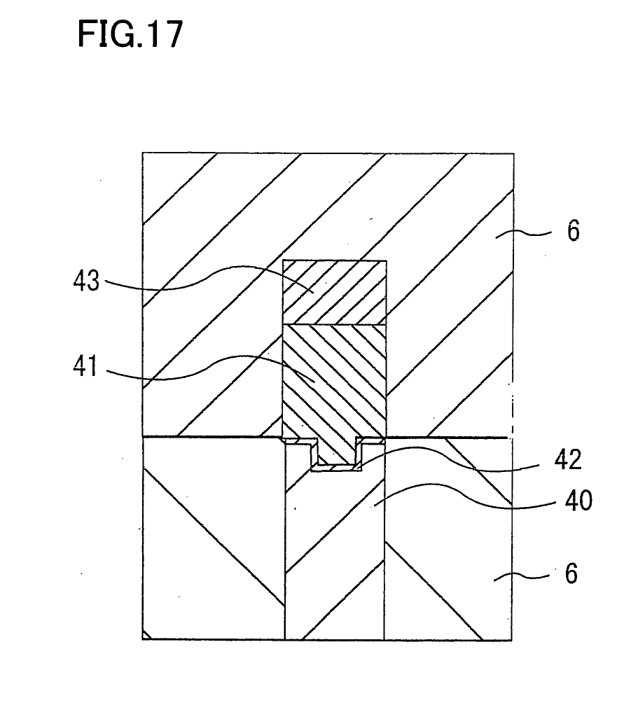

FIG. 17 is a schematic sectional diagram explaining an eighth embodiment related to the semiconductor device of the present invention.

The cross-sectional shape of the connection surface between said cell contact 40 and said bit contact 41 is not limited to the step shape exemplified by FIGS. 11, 16, etc. For example, as shown in FIG. 17, the cross-sectional shape of the connection surface between said cell contact 40 and said bit contact 41 may be in shape of concave and convex which are assembled with each other.

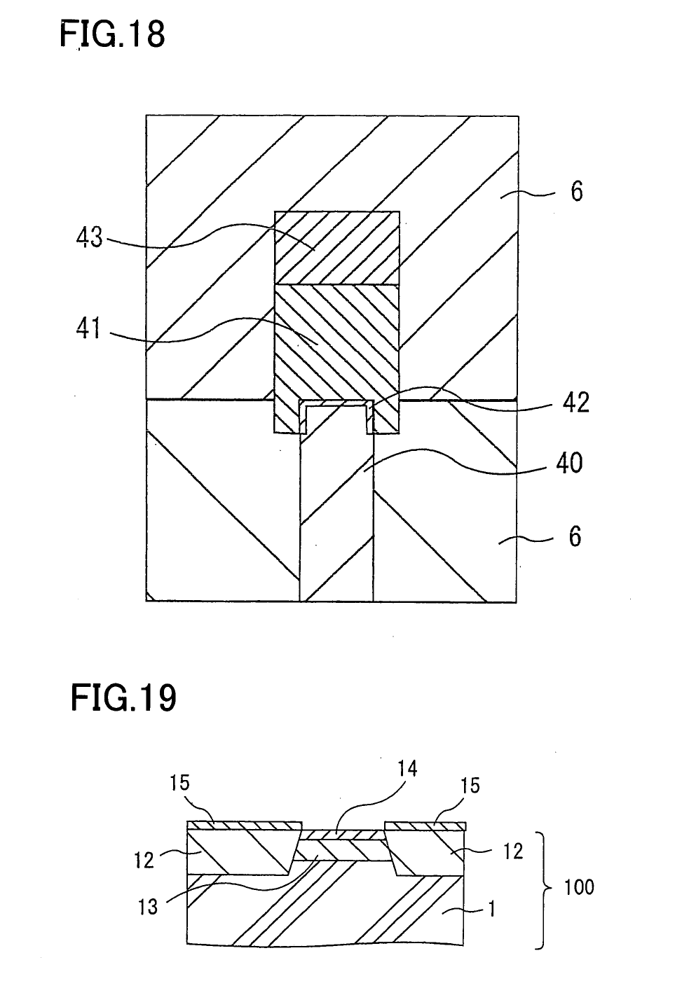

FIG. 18 is a schematic sectional diagram explaining a ninth embodiment related to the semiconductor device of the present invention.

A relation of the connection surface between said cell contact 40 and said bit contacet 41 is conversed with that of the eighth embodiment. These surface cross-sectional shapes are formed by assembling concave-convex shapes with each other.

Next a method of manufacturing the semiconductor device related to the present invention will be described.

FIG. 19 is a schematic sectional diagram explaining a method of forming a MOS field-effect transistor 100 on the semiconductor substrate.

A semiconductor substrate 1 of the present invention is for example a semiconductor silicon substrate. The semiconductor silicon substrate employed in the present invention is not especially limited and commercial product is usable.

As shown in FIG. 19, first a shallow slot is formed in a semiconductor substrate 1, and an insulation material is buried in this slot to form an isolation insulator layer 12.

Cells in a memory array region in said semiconductor substrate are individually divided by this isolation insulator layer 12.

And an impurity is introduced into said semiconductor substrate 1 divided by this isolation insulator film 12 to form a source/drain region 13. Said source/drain region 13 is silicided by cobalt at an upper end to form cobalt silicide layer 14. A gate electrode (not shown) corresponding to said source drain region is separately provided.

Then, the predetermined surface of said isolation insulator film 12 and said MOS field-effect transistor 100 is covered with silicon nitride layer 15

With these processes, said MOS field-effect transistor 100 can be formed as a transistor for memory cells.

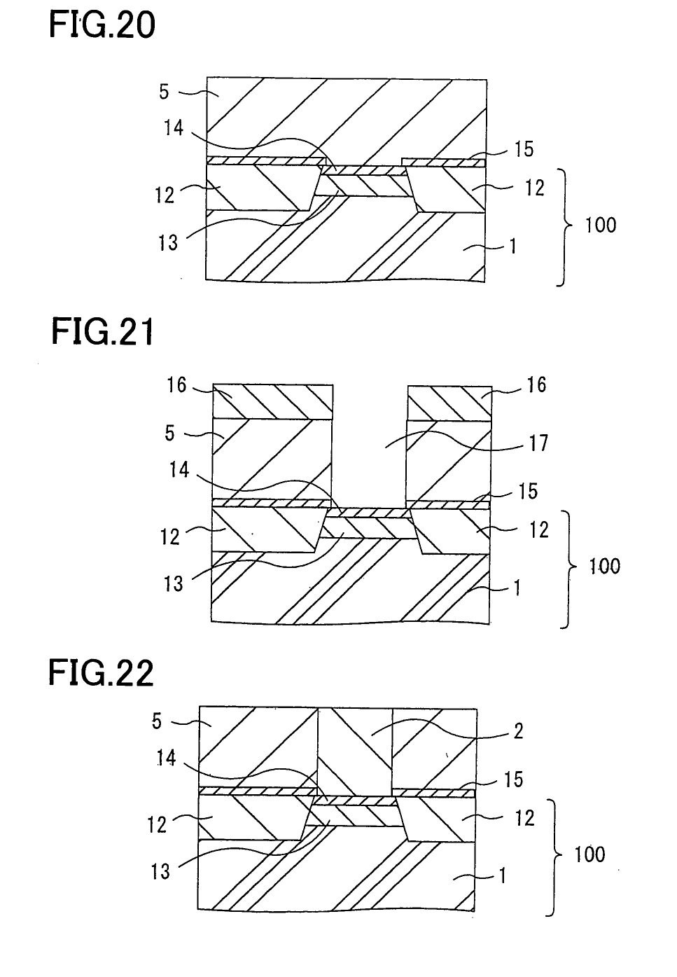

FIG. 20 is a schematic sectional diagram explaining a process of forming a cell contact 2 electrically connected to said MOS field-effect transistor 100.

As shown in FIG. 20, a first interlayer insulation film 5 covering said MOS field-effect transistor 100 is formed by a method for depositing insulation material such as silicon oxide on the whole surface of silicon nitride layer 15 of said MOS field-effect transistor 100, said isolation insulator file 12 and others.

Subsequently, a photo resist layer 16 is formed on said first insulation layer 5 and a resist pattern is formed by a known lithography process for a cell contact.

As shown in FIG. 21, a contact hole 17 is formed by a selective etching to open for a cell contact electrically connected to said transistor with the resister pattern as a mask.

Next, as shown in FIG. 22, a cell contact 2 electrically connected to said MOS field-effect transistor 100 can be formed by removing said photo resist layer 16, and by an ashing process and a stripping process after burying polysilicon in said contact hall 17.

A length of said cell contact 2 in a direction normal to said semiconductor substrate 1 is generally in a range from 400 to 800 nm, preferably 550 to 750 nm, and more preferably 600 to 650 nm.

Said polysilicon is added with p-type impurity such as boron, and n-type impurity such as phosphorus and said cell contact 2 can be passed through with electric current.

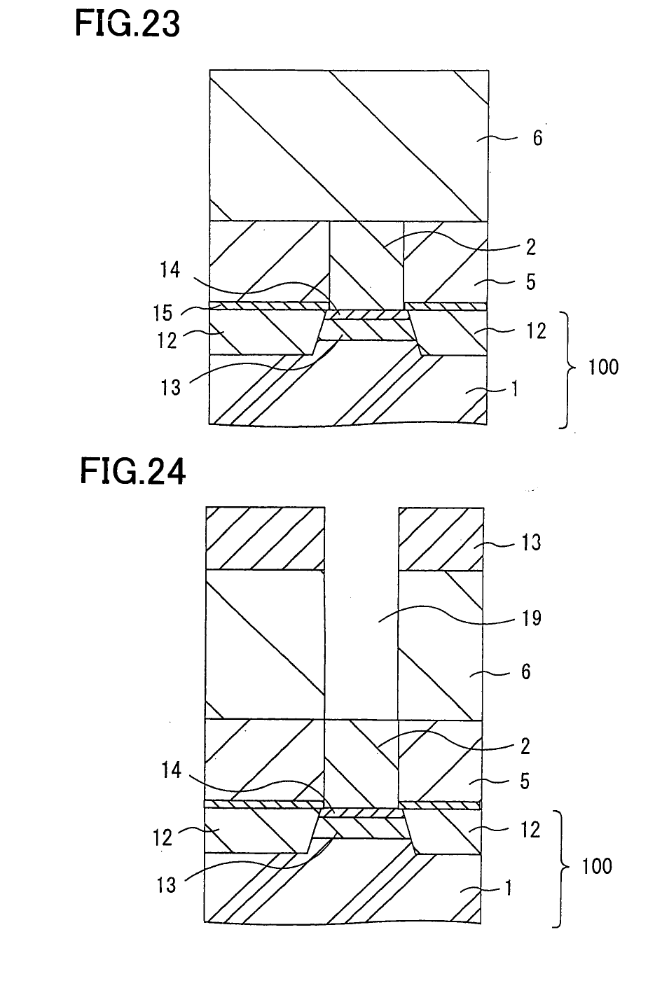

FIG. 23 is a schematic sectional diagram explaining a process of forming a capacitance contact 3 electrically connected to said cell contact 2.

As shown in FIG. 23, a second interlayer insulation film 6 covering said cell contact 2 can be formed by a method for depositing insulation material such as silicon oxide on the whole surface of said first interlay insulator film 5 and said cell contact 2.

Subsequently, a photo resist layer 18 is formed on said second insulation layer 6 and a resist pattern is formed by a known lithography process for a capacitance contact.

As shown in FIG. 24, a contact hole 19 is formed by a selective etching to open for a capacitance contact electrically connected to said cell contact 2 with the resist pattern as a mask.

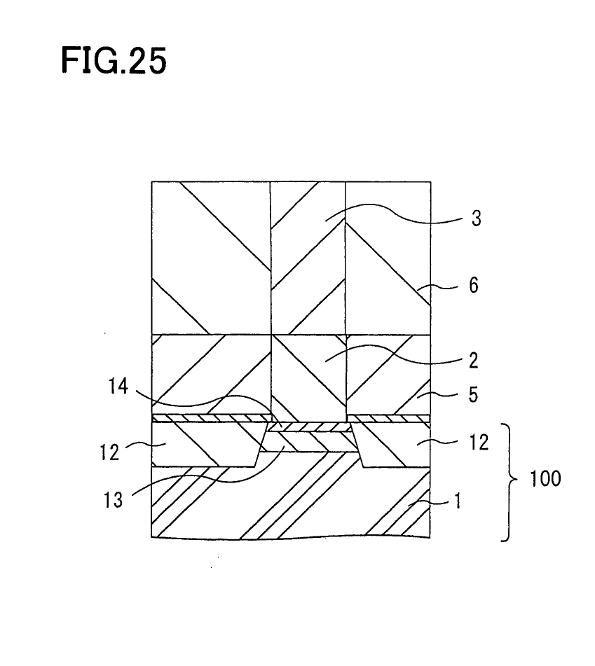

Next, as shown in FIG. 25, a capacitance contact 3 electrically connected to said cell contact 2 can be formed by removing said photo resist layer 18 by an ashing process and a stripping process after burying polysilicon in said contact hall 19.

Said polysilicon is added with p-type impurity such as boron, and n-type impurity such as phosphoric acid and said capacitance contact 3 can be passed through with electric current, as well as the case of said cell contact 2.

A length of said capacitance contact 3 in a direction of perpendicular to said semiconductor substrate 1 (normal direction to said semiconductor substrate surface) is generally in a range from 300 to 700 nm, preferably 400 to 600 nm, and more preferably 450 to 550 nm.

The method for manufacturing said cell contact 2 and said capacitance contact 3 by one step method was explained above. However, polysilicon may be buried in series for said contact hole 17 or said contact hole 19.

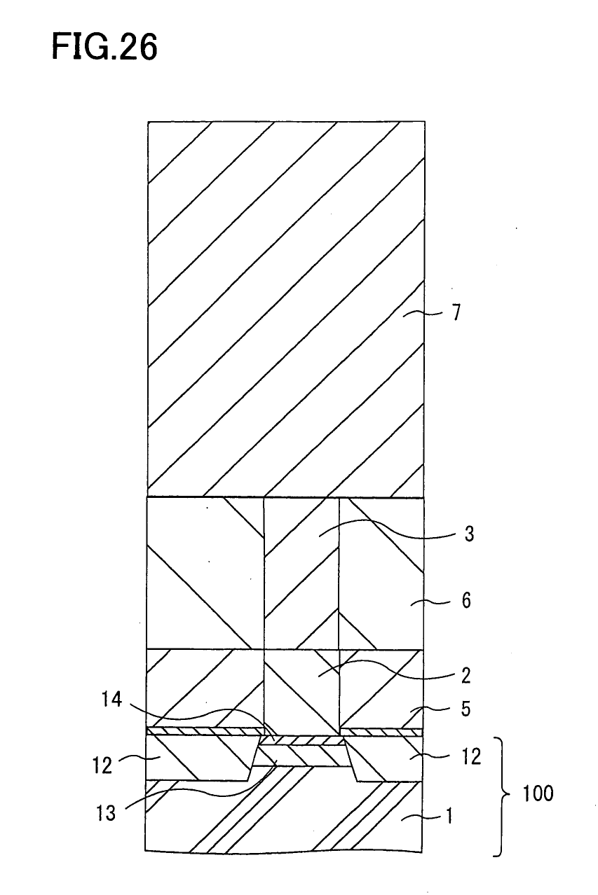

FIG. 26 is a schematic sectional diagram explaining a process of etching said capacitance contact 3, said second interlayer insulation film 6 and the third interlay insulation film 7 in a direction normal to said semiconductor substrate.

With a method of depositing insulation material such as silicon oxide to the whole surface of said second interlay insulation film 6 and said capacitance contact 3 using TEOS

(Terraethoxysilane) and others, the third interlayer insulation film 7 covering said capacitance contact 3 is formed as shown in FIG. 26.

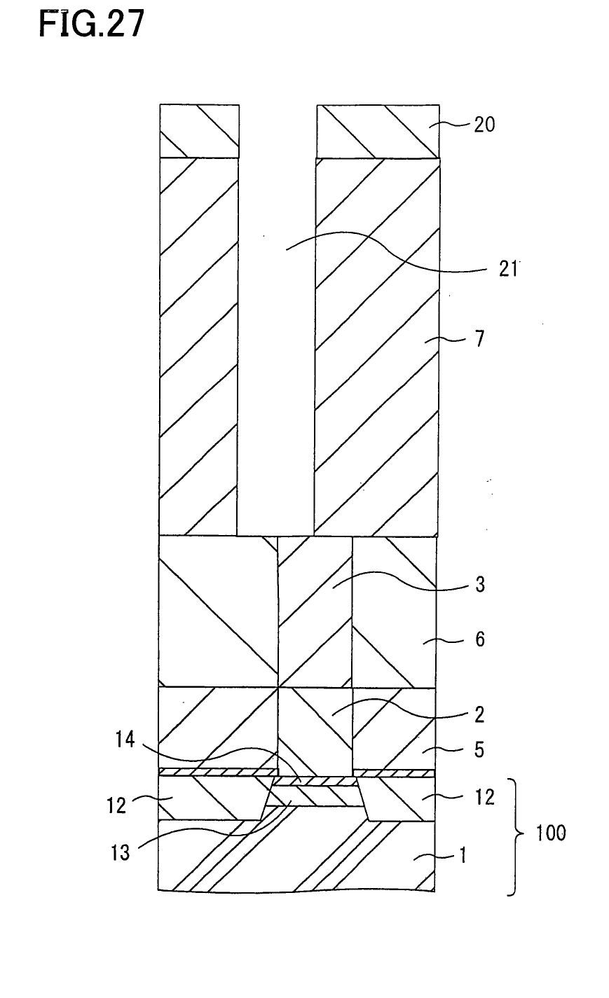

As shown in FIG. 27, a photo resist layer 20 is formed on said third interlayer insulation film 7 to form a resist pattern for a capacitance element by a known lithography process.

With this resist pattern as a mask, the etching process is performed.

Said third interlayer insulation film 7 as shown in FIG. 27 is removed by reactive ion etching which is performed, for example, with gas for etching: CF₄/O₂/Ar, CHF₃/O₂/Ar, C₄F₈/O₂/Ar, etc., under conditions of Ar: 20 volume %, temperature: 40 to 60° C., pressure: 50 to 100 m torr, high frequency power: 3000 W, bias: 2000 W.

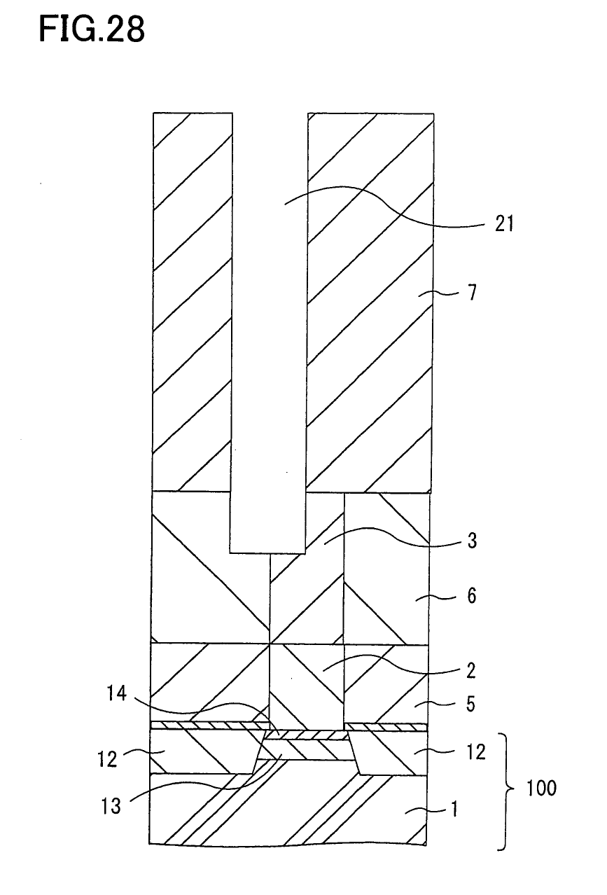

Further, polysilicon of said capacitance contact 3 as shown in FIG. 28 is partly removed by continuing the reactive ion etching.

In this case, said second interlayer insulation film 6 alone is removed by reactive ion etching which is performed, for example, with gas for etching: C₄F₈/C₄F₆/O₂/Ar, etc., flow rate: 15 ml/min. for C₄F₈, 10 ml/min. for C₄F₆, 20 ml/min. for O₂, 150 ml/min. for Ar, pressure: 15 m torr, high frequency power: 3000 W, bias: 2000 W. And then, polysilicon of said capacitance contact 3 may be partly removed by reactive ion etching which is performed, for example, gas for etching: Cl₂/HBr/O₂, etc., flow rate: 10 ml/min. for Cl₂, 180 ml/min. for HBr, 5 ml/min. for O₂, pressure: 15 m torr, high frequency power: 3000 W, bias: 2000 W.

Further, said second interlayer insulation, film 6 and a part of polysilicon of said capacitance contact 3 may be simultaneously removed by plasma etching which is performed with gas for etching: CHF₃/CF₄/O₂, etc., flow rate adjusted to: 100 ml/min. for these gases in total and 30 to 40 ml/min. for O₂, frequency: 13.56 MHz.

Next, the contact hole 21 as shown in FIG. 28 is obtained by removing said resist pattern by ashing process, stripping process, etc.

Depth of said contact hole 21 is in a range, preferably from 1 to 5 μm, more preferably 2 to 4 μm with respect of a distance between upper end of said third interlayer insulation film 7 to bottom face of said contact hole 21.

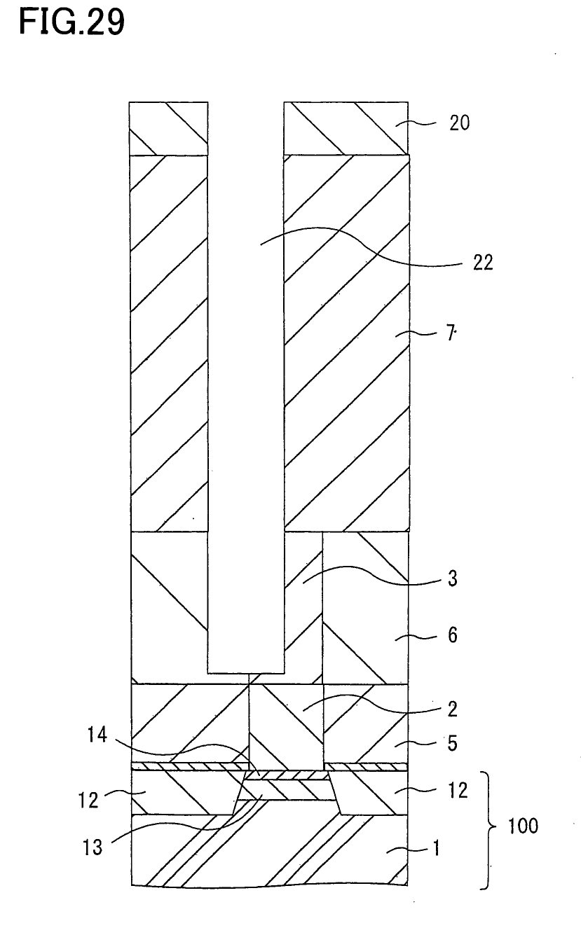

FIG. 29 is a schematic sectional diagram explaining a process of forming a contact hole 22 of second embodiment by etching said capacitance contact 3, said second interlayer insulation film 6 and said third interlayer insulation film 7 in a direction normal to said semiconductor substrate.

By the same process of obtaining the contact hole 21 as shown in FIG. 28 through the same etching process as explained above, etching of said contact hole 21 and said capacitance contact 3 is continued. With this process, the bottom face of said contact hole 22 is provided in such way that it is located near said first interlayer insulation film 5.

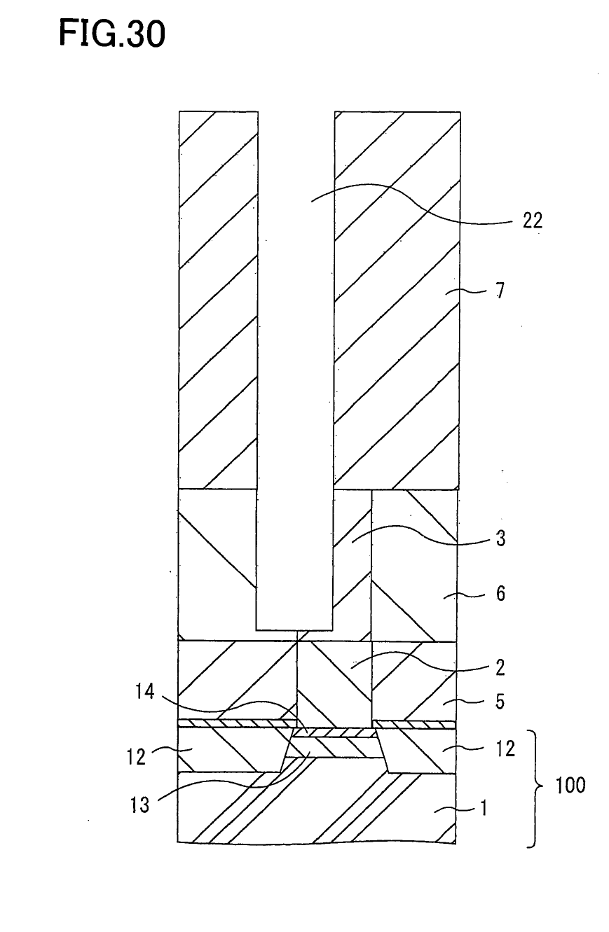

Next, said resist pattern is removed by ashing process, stripping process, etc. to obtain the contact hole 22 as shown in FIG. 30.

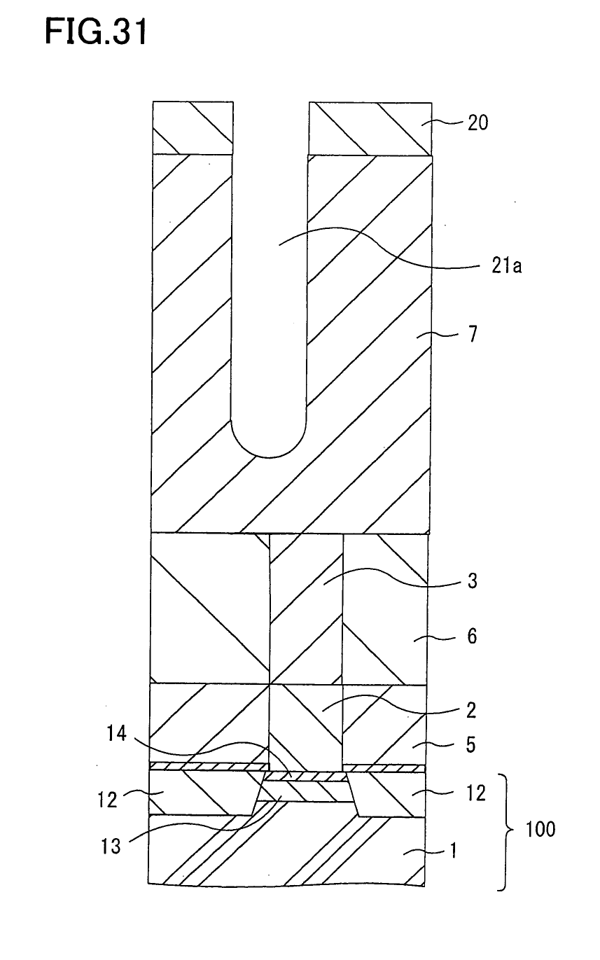

FIG. 31 is a schematic sectional diagram explaining a process of forming a contact hole 21a of the contact hole 21 of the first embodiment.

By the same process of obtaining the contact hole 21 as shown in FIG. 31, through the same etching process as explained above, etching of said contact hole 21a and said capacitance contact 3 is continued.

In this case, a shape of the bottom face of the contact hole 21a can be adjusted to substantially sphere by increasing a flow rate of the etching gas. The same as above.

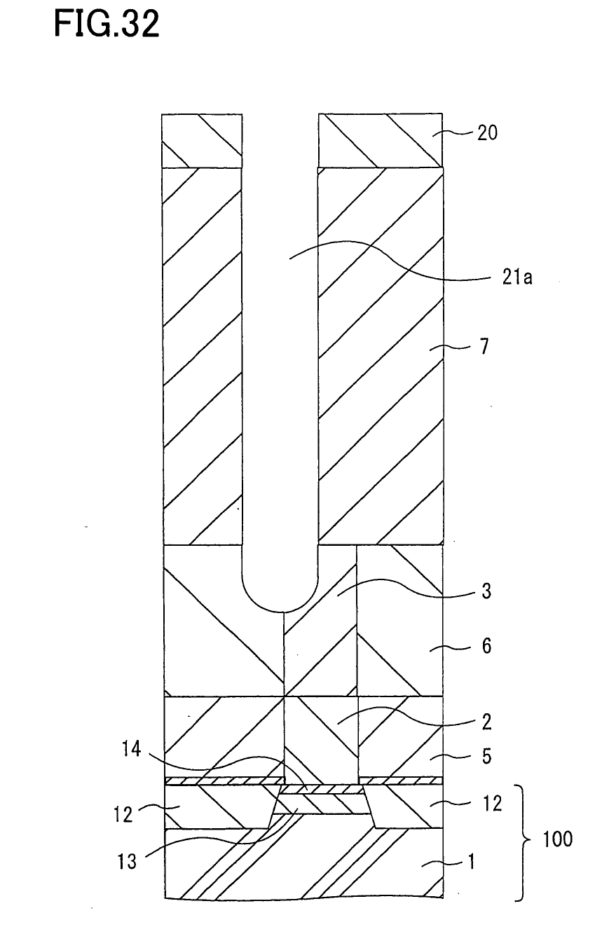

Preferably, said capacitance contact 3 and said second interlayer insulation layer 6 are simultaneously etched. With this process, curved face can be included in inner surface of said contact hole 21a as shown in FIG. 32.

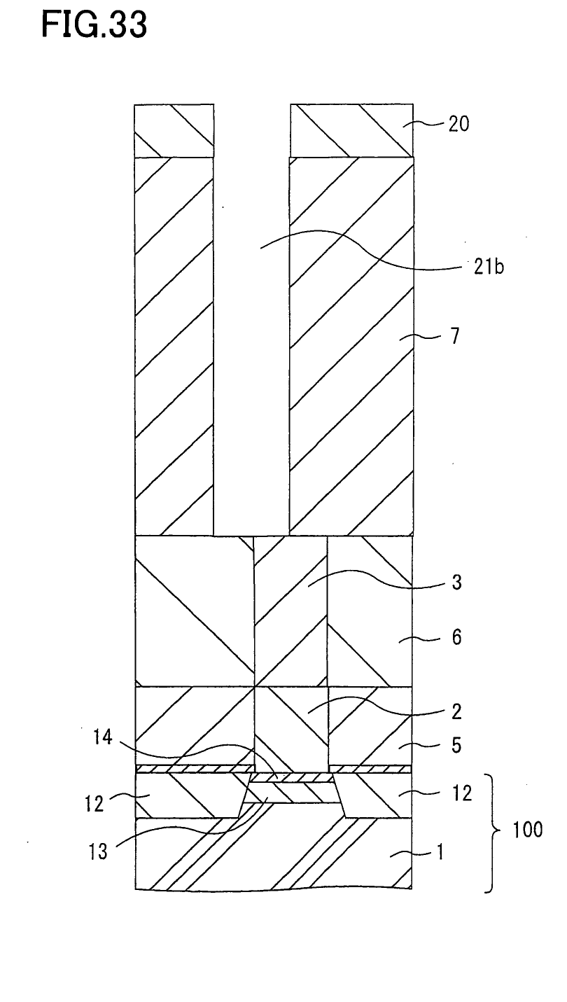

FIG. 33 is a schematic sectional diagram explaining a process of a contact hole 21b of another modification example of forming of said first embodiment.

By the same process of obtaining the contact hole 21 as shown in FIG. 27, through the same etching process as explained above, etching of said contact hole 21b and said capacitance contact 3 is continued.

In this case, an etching speed of said capacitance contact 3 and said second interlayer insulation film 6 can be made substantially same by plasma etching which is performed with gas for etching: CHF₃/CF₄/O₂, etc., flow rate adjusted to: 100 ml/min. for these gases in total, frequency: 13.56 MHz.

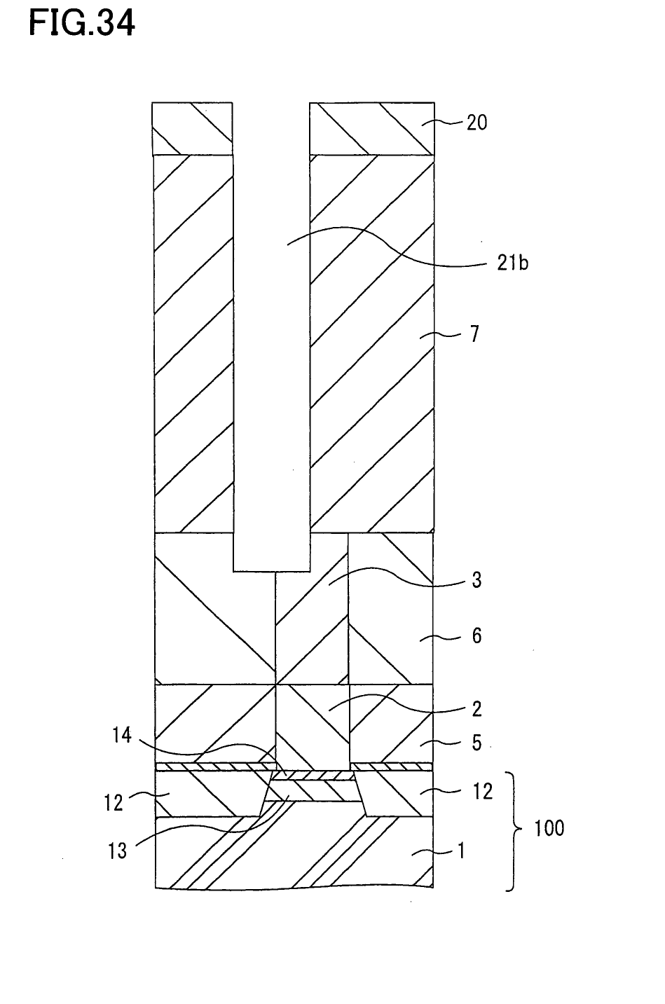

With this, the bottom portion of said contact hole 21n as shown in FIG. 34 can be kept in substantially horizontal position.

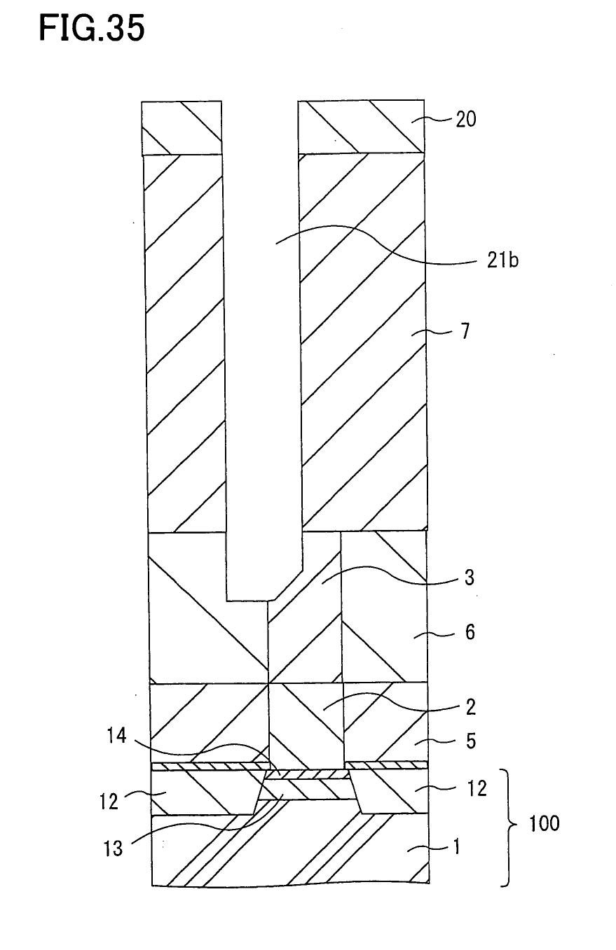

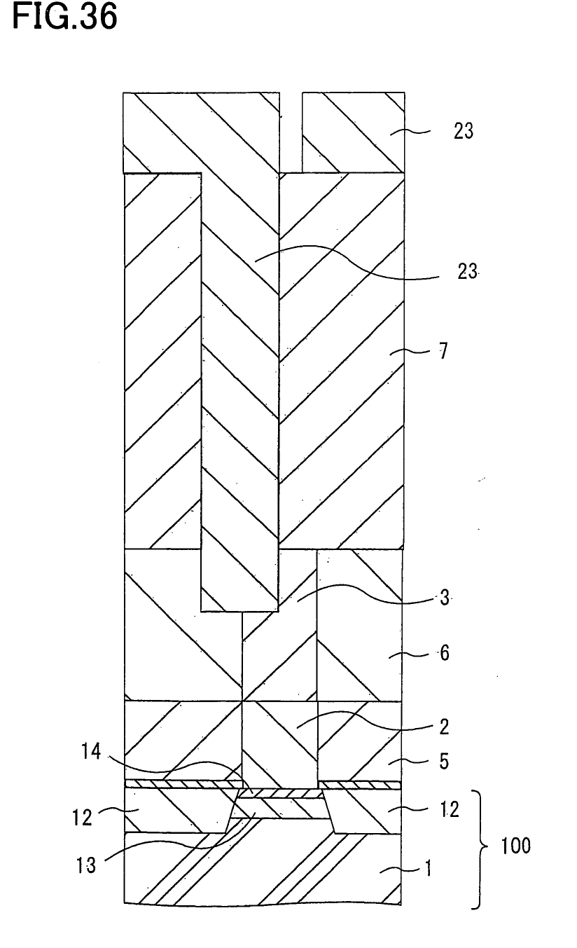

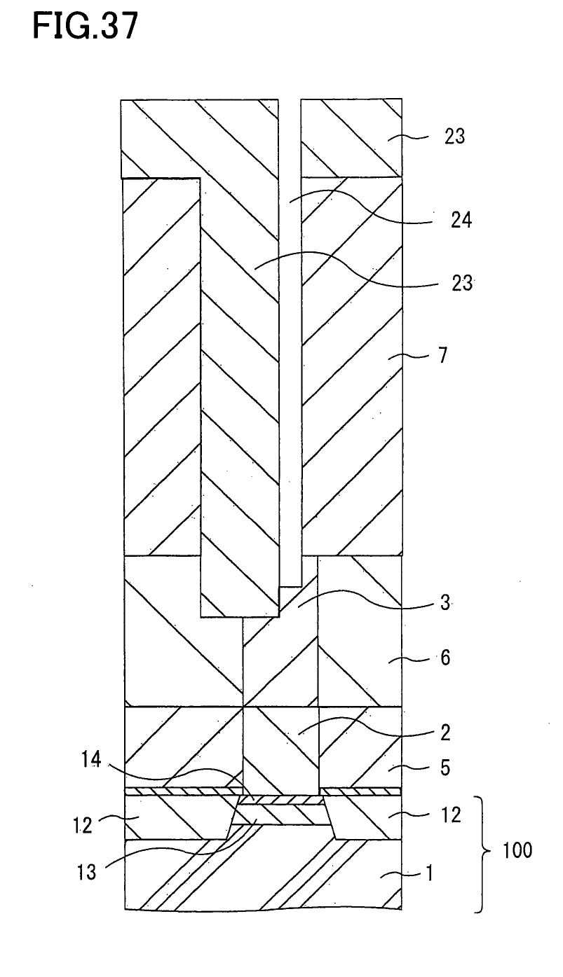

Next, for example, a portion of said second interlayer insulation film 6 can be etched more faster than that of said capacitance contact 6 by decreasing the component rate of etching gas, CF₄., thereby forming slope included in the inner surface of said contact hole 21 as shown in FIG. 35. It is similar processing as follows.

FIG. 36 is a schematic sectional diagram explaining a process of forming a contact hole 24 of said third embodiment by etching the said capacitance contact 3, said second interlayer insulation film 6 and third interlayer insulation film in a direction normal to said semiconductor substrate.

A photo resist layer 23 is formed on said contact hole 21 and said third interlayer insulation film 7 as in above mentioned FIG. 28. Next, a resist pattern is formed by a known lithography process for capacitance element. As a result, said contact hole 21 is buried by said photo resist layer 23 as shown in FIG. 36.

With this resist pattern as a mask, etching process can be performed.

Said third interlayer insulation film 7 as shown in FIG. 36 can be removed by plasma etching using said etching gas.

Subsequently, polysilicon of said capacitance contact 3 can be partly removed as shown in FIG. 36 by continuing said plasma etching.

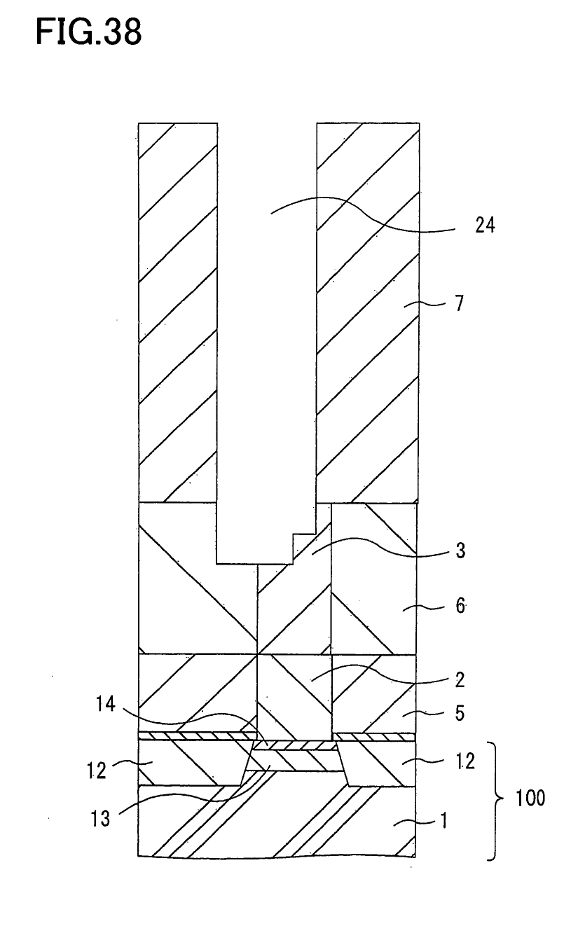

Next, said resist pattern is removed by ashing process, stripping process, and others to obtain contact hole 24 as shown in FIG. 38.

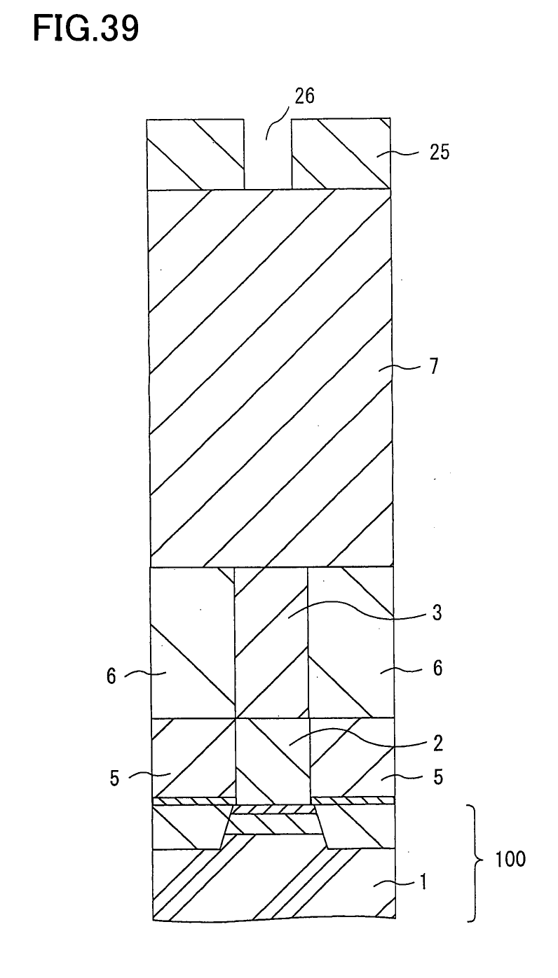

FIG. 39 is a schematic sectional diagram explaining a process of forming a contact hole 26 of fourth embodiment by etching said capacitance contact 3 and said third interlayer insulation film 7 in a direction normal to said semiconductor substrate.

With a method of depositing insulation material such as silicon oxide to the whole surface of said second interlay insulation film 6 and said capacitance contact 3 using TEOS (Terraethoxysilane) and others, the third interlayer insulation film 7 covering said capacitance contact 3 is formed as shown in FIG. 25.

As shown in FIG. 39, a photo resist layer 25 is formed on said third interlayer insulation film 7 to form a resist pattern for a capacitance element by a known lithography process.

With this resist pattern as a mask, the etching process is performed.

Said third interlayer insulation film 7 as shown in FIG. 39 can be removed by plasma etching using above mentioned etching gas.

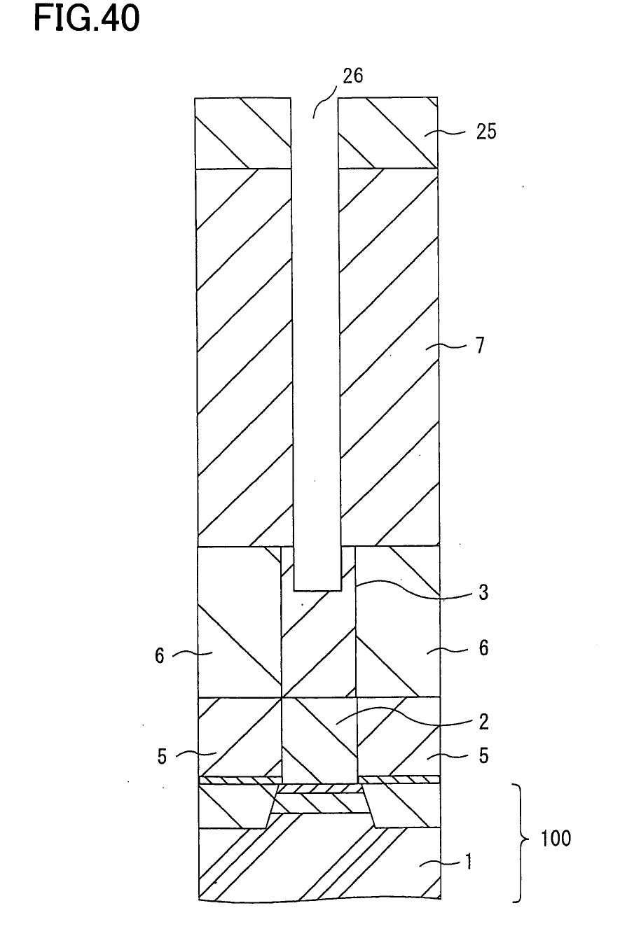

Further, polysilicon of said capacitance contact 3 as shown in FIG. 40 can be partly removed by continuing said plasma etching.

With these operations, a contact hole 26 can be formed.

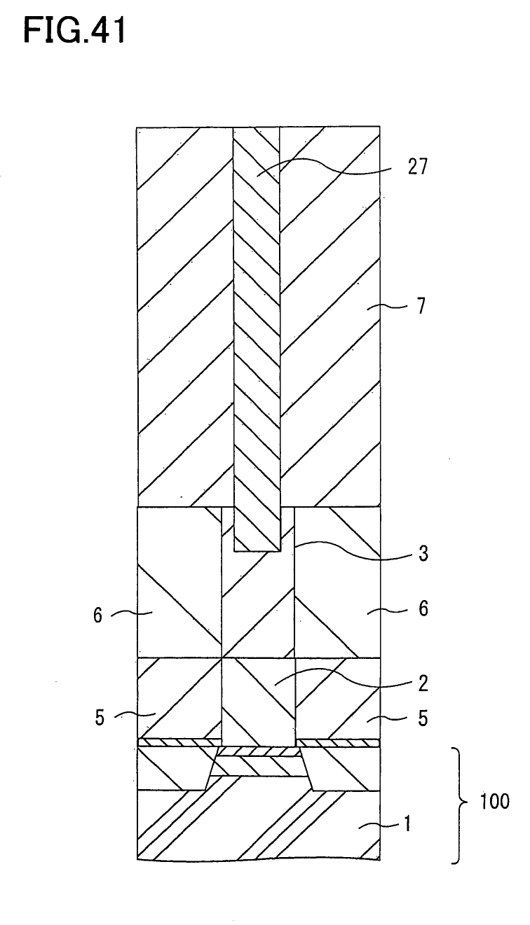

Next, after said resist pattern is removed by ashing process, stripping process, and others, the photo resist layer 27 can be buried in said contact hole 26 and hardened as shown in FIG. 41.

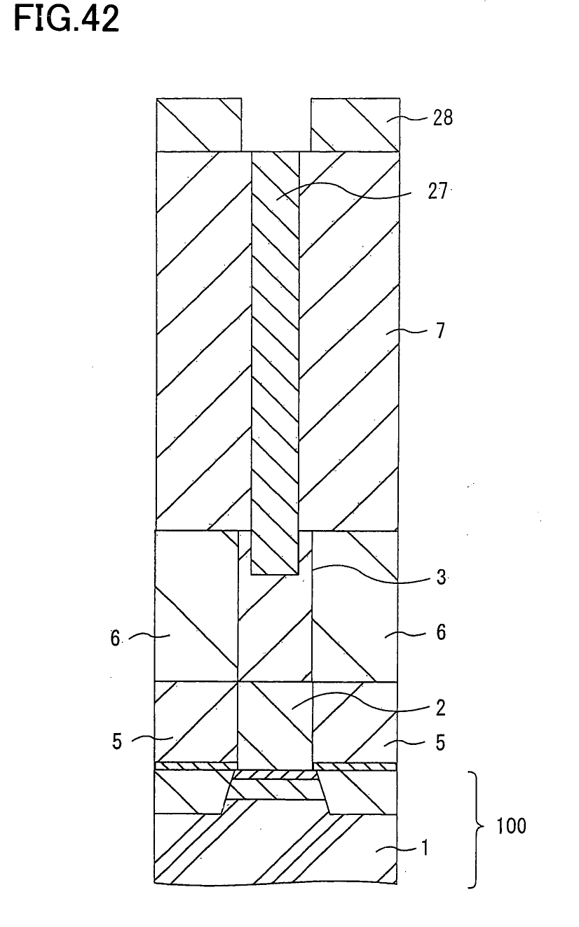

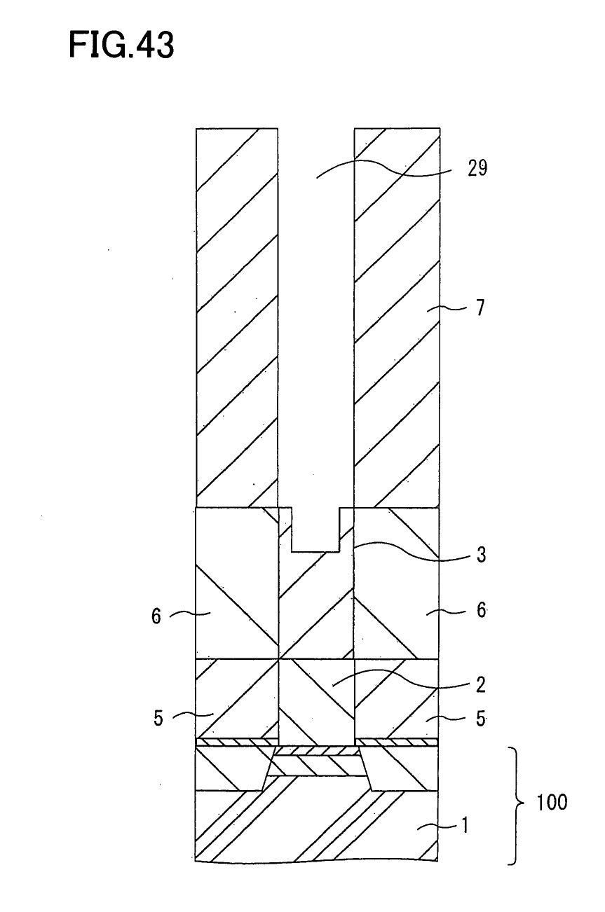

Further, as shown in FIG. 42, a photo resist layer 28 is formed on said third interlayer insulation film 7 and said photo resist layer 27 to form a resist pattern for a capacitance element by a known lithography process.

With this resist pattern as a mask, the etching process is performed.

Said third interlayer insulation film 7 as shown in FIG. 42 can be removed by plasma etching using above mentioned etching gas.

Next, said resist pattern is removed by ashing process, stripping process, and others, to obtain a contact hole 29.

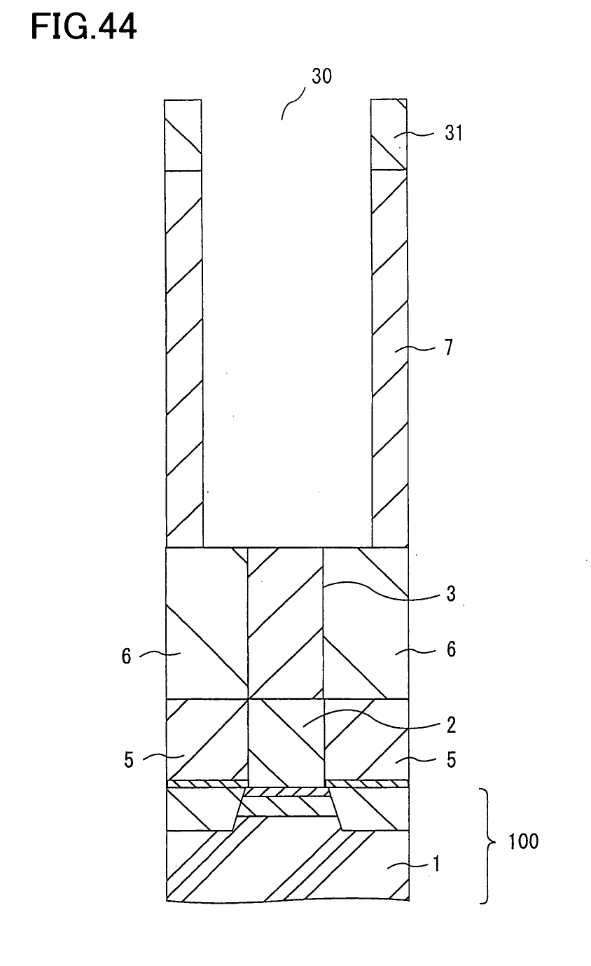

FIG. 44 is a schematic sectional diagram explaining a process of forming a contact hole 30 of fourth embodiment by etching said capacitance contact 3 and said third interlayer insulation film 7 in a direction normal to said semiconductor substrate.

With a method of depositing insulation material such as silicon oxide to the whole surface of said second interlayer insulation film 6 and said capacitance contact 3 using TEOS (Terraethoxysilane) and others, the third interlayer insulation film 7 covering said capacitance contact 3 is formed as shown in FIG. 25.

Subsequently a photo resist layer 31 is formed on said third interlayer insulation film 7 to form a resist pattern for a capacitance element by a known lithography process.

With this resist pattern as a mask, the etching process is performed.

Said third interlayer insulation film 7 as shown in FIG. 44 can be removed by plasma etching using above mentioned etching gas.

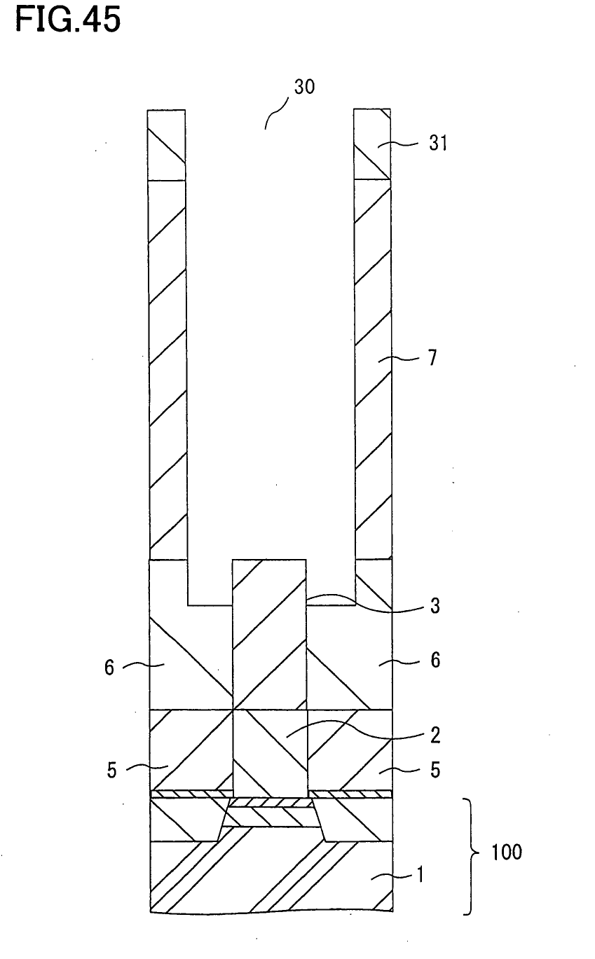

Further, said second interlayer insulation film 6 alone can be removed without removing polysilicon of said capacitance contact 3 as shown in FIG. 45 by previously mentioned reactive ion etching. With these operations, a contract hole 30 can be formed.

And after said resist pattern is removed by ashing process, stripping process and others, said contact hole 30 can be obtained as shown in FIG. 46.

Next, a process forming the capacitance element will be explained.

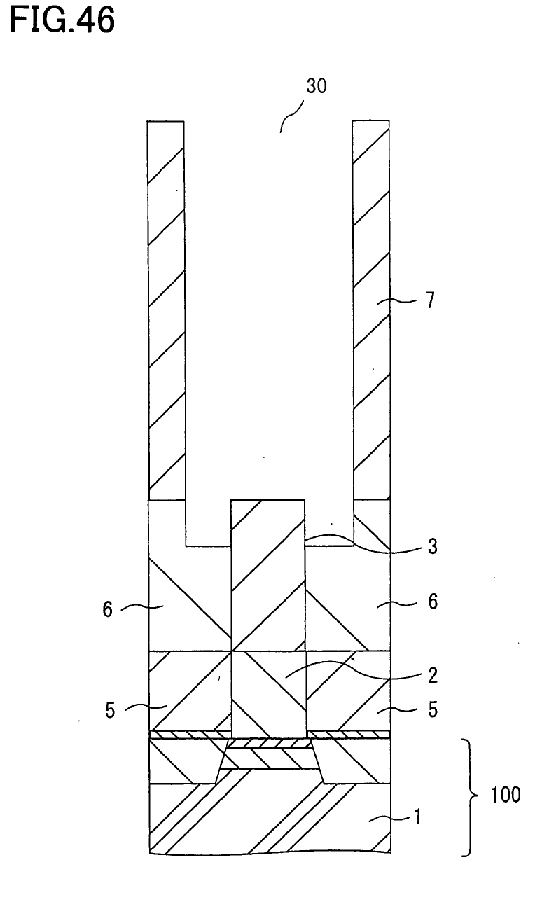

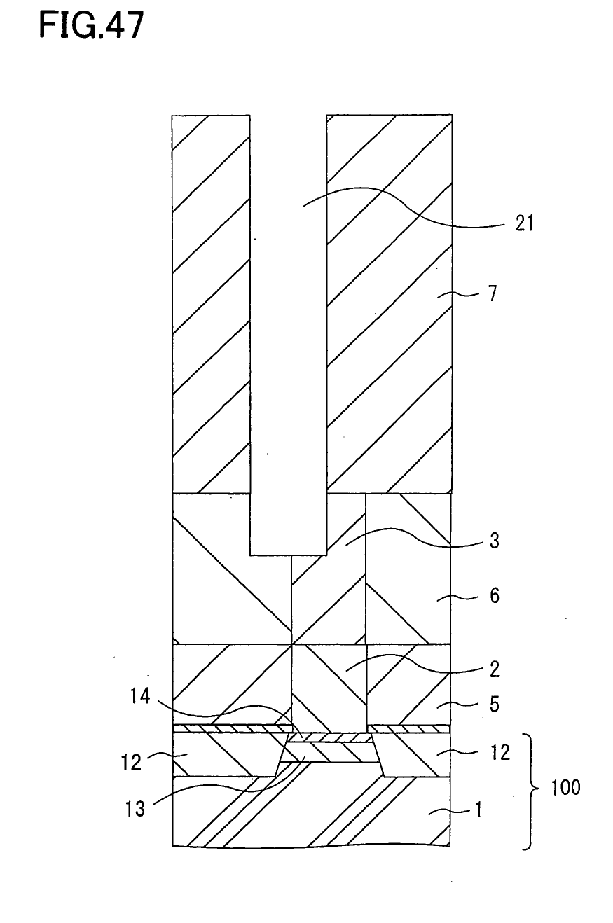

FIG. 47 is a schematic sectional diagram explaining a process of forming said capacitance element 400 of said first embodiment by forming a lower electrode 10, a capacitance film 9 and an upper electrode 8 inside said capacitance contact hole 21.

First, an oxide film inside the contact hole 21 is removed as shown in FIG. 47.

Next, under conditions of temperature in a range from 600 to 700° C., Ti is deposited inside said contact hole 21 by a CVD method with thickness in a range from 5 to 20 nm, preferably 10 to 20 nm. Further under the same temperature, TiN is deposited by a CVD method with thickness in a range from 10 to 30 nm, preferably 15 to 25 nm.

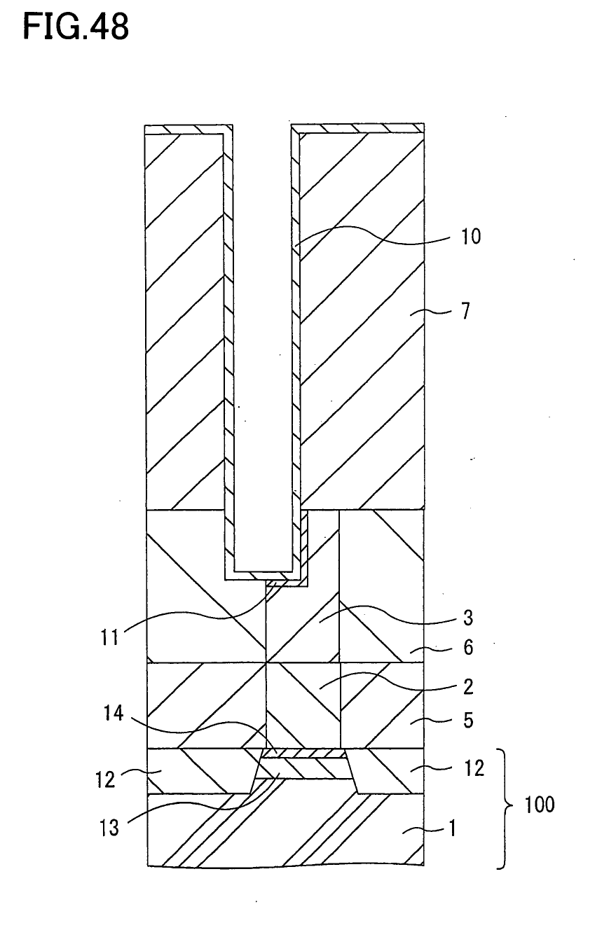

And then, TiSi layer 11 and the lower electrode 10 is formed on said capacitance contact 3, as shown in FIG. 48, by etch backing said TiN while supplying Cl₂ at a speed of 40 ml/min. and Ar at 40 ml/min. under a pressure of 1.0×10⁻² torr.

Subsequently, by a CVD method, a capacitance film 9 can be formed by depositing Al₂O₃ on a surface of said lower electrode 10 with thickness in a range from 2 to 5 nm, and HfO₂ in a range from 3 to 6 nm.

Next, the upper electrode 8 is formed by depositing TiN on a surface of said capacitance film 9 under conditions of 450 to 550° C. by a CVD method.

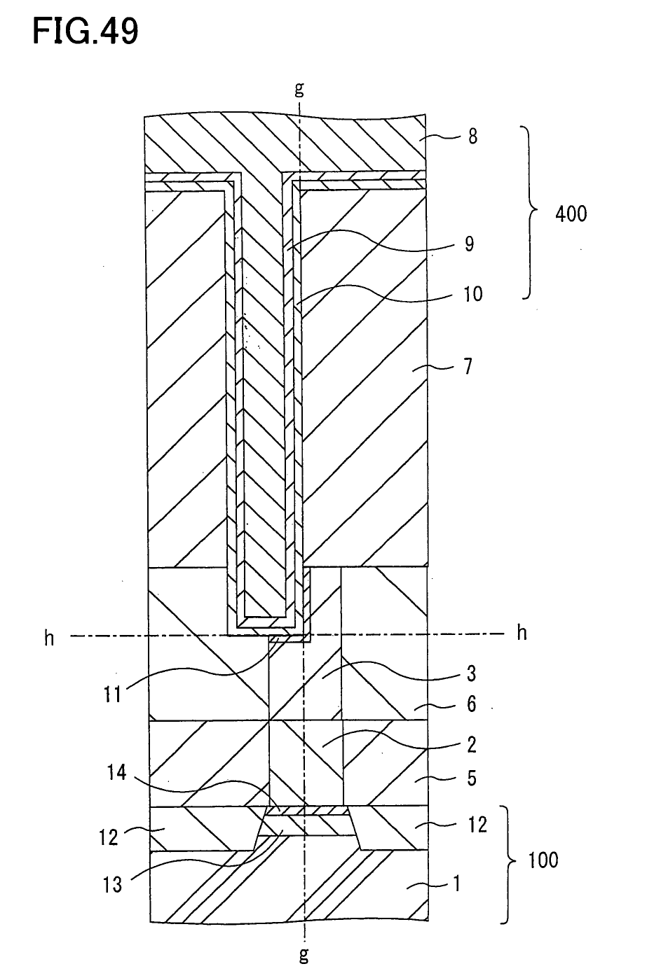

With this process, a capacitance element 400 electrically connected to said capacitance contact 3 can be formed as shown in FIG. 49.

With respect to said capacitance contact 3, said capacitance element 400 includes a portion electrically connected in a normal direction with said semiconductor substrate (a dot-dash line g-g) and a portion electrically connected in a parallel direction with said semi conductor substrate (a dot-dash line h-h).

In the same way, with respect the contact hole as shown by the second embodiment to the fifth embodiment, the capacitance element comprising the TiSi layer 11, the lower electrode 10, the capacitance film 9 and the upper electrode 8 can be formed.

Thus, semiconductor device according to the first embodiment to the fifth embodiment of the present invention is manufactured.

FIG. 50 is a schematic sectional diagram explaining a process of forming said cell contact 40, said bit contact 41, and said bit line 43 which are included in the sixth embodiment of the present invention.

A process of forming the contact cell 40 on the first interlayer insulation film 5 covering said MOS field-effect transistor 100 is the same with that of the first embodiment of the present invention as mentioned previously.

By a method of depositing insulation material such as silicon oxide on the whole surface of said first interlayer insulation film 5 and said cell contact 40, an inter layer insulation film 60 covering said cell contact 40 can be formed.

Next, a photo resist layer is formed on said interlayer insulation film 60 (not shown), and a resist pattern is formed for capacitance contact by a known lithography process.

With this resist patter as a mask, a contact hole 44 is opened by selective etching for the bit contact 41 electrically connected to said cell contact 40 as shown in FIG. 50.

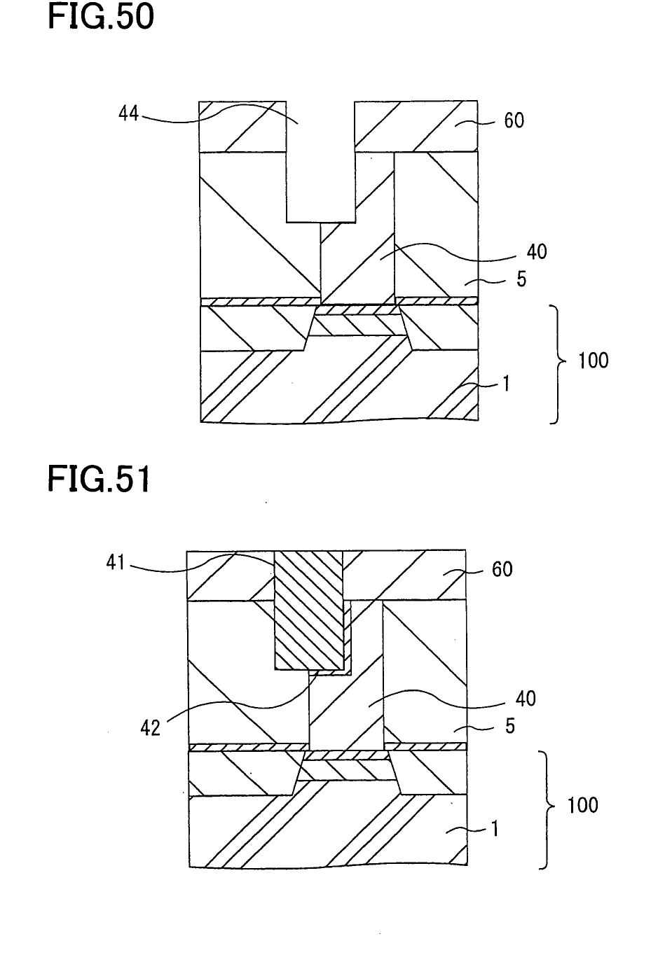

Subsequently, after removing the oxide film inside said contact hole 44, a WSi2 layer 42 is formed on the boundary surface of the cell contact 40 at the bottom face of said contact hole 44, and the bit contact 41 is formed as shown in FIG. 51 by burying W in said contact hole.

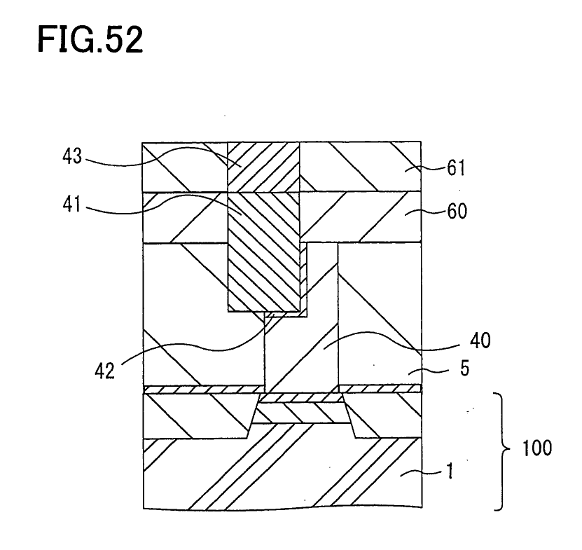

Similarly, a bit line 43 formed of W electrically connected to said bit contact 41 is formed as shown in FIG. 52.

Thus, with this method, semiconductor device according to the sixth embodiment to the ninth embodiment of the present invention as previously described can be manufactured.

With the semiconductor device of the present invention obtained in this way, a connection area between said capacitance element and said capacitance contact is larger than that of the conventional semiconductor device, thereby electric power saving is realized.

The present invention is not limited to the above described embodiments, and various variations and modifications may be possible without departing from the scope of the present invention.

This application is based on the Japanese Patent application No. 2006-192226 filed on Jul. 12, 2006, entire content of which is expressly incorporated by reference herein.

What is claimed is:

1. A semiconductor device comprising:
a semiconductor substrate;
a transistor formed on the said semiconductor substrate;
a first electric element electrically connected to said transistor; and
a second electric element electrically connected to said first electric element;
wherein said first electric element and said second electric element are connected in such say that at least two planes are parallel to said semiconductor substrate surface and passing through both of said first electric element and said second electric element.

2. A semiconductor device comprising:
a transistor semiconductor substrate;
a transistor formed on said semiconductor substrate;
a cell contact electrically connected to said transistor;
a capacitance contact electrically connected to said cell contact; and
a capacitance element electrically connected to said capacitance contact,
wherein said capacitance contact and said capacitance element are connected in such way that at least two planes are parallel to said semiconductor substrate surface and passing through both of said capacitance contact and said capacitance element.

3. The semiconductor device according to claim 2, wherein a connection surface of said capacitance contact and said capacitance element comprises a connection portion in parallel direction with said semiconductor substrate surface and a connection portion in perpendicular direction with said semiconductor substrate surface.

4. The semiconductor device according to claim 2, wherein said capacitance contact comprises at least one step (A) at end portion connected to said capacitance element, said capacitance element is assembled in such way that said capacitance element is electrically connected to at least one portion of said step (A)

5. The semiconductor device according to claim 3, wherein said capacitance contact comprises at least one step (A) at end portion connected to said capacitance element, said capacitance element is assembled in such way that said capacitance element is electrically connected to at least one portion of said step (A)

6. The semiconductor device according to claim 2, wherein said capacitance element comprises a lower electrode and an upper electrode.

7. A method of manufacturing a semiconductor device in which a capacitance element electrically connected to a transistor is formed on an upper layer of said transistor formed on a semiconductor substrate comprising steps of:
(a) forming a transistor on the semiconductor substrate;
(b) forming a first interlayer insulation film covering said transistor,
(c) forming a cell contact electrically connected to said transistor in said first interlayer insulation film,
(d) forming a second interlayer insulation film covering said first interlayer insulation film and said cell contact,
(e) forming a capacitance contact electrically connected to said cell contact in said second interlayer insulation film,
(f) forming a third interlayer insulation film covering said second interlayer insulation film and said capacitance contact,
(g) etching at least one selected from a group of said capacitance contact, said second interlayer insulation film and said third interlayer insulation film in perpendicular direction of said semiconductor substrate, and
(h) forming a capacitance element comprising a portion electrically connected in parallel direction with said semiconductor substrate, and a portion electrically connected to said semiconductor substrate in perpendicular direction, with respect to said capacitance contact.

8. The method of manufacturing a semiconductor device according to claim 7, wherein the step (h) of forming said capacitance element comprises a step of forming a lower electrode, a capacitance film and an upper electrode.

9. A semiconductor device comprising:
a semiconductor substrate;
a transistor formed on said semiconductor substrate;
a cell contact electrically connected to said transistor;
a bit contact electrically connected to said cell contact; and
a bit line electrically connected to said bit contact;
wherein said cell contact and said bit contact are connected in such way that at least two planes are parallel with said semiconductor substrate surface and passing through both of said cell contact and said bit contact.

10. The semiconductor device according to claim 9, wherein a connection surface between said cell contact and said bit contact has a connection portion parallel with said semiconductor substrate surface, and a connection portion perpendicular with said semiconductor substrate surface.

11. The semiconductor device according to claim 9, wherein said cell contact comprises at least one step (A) at end portion connected to said bit contact, and said bit contact is assembled so as to be electrically connected to at least one portion.

12. The semiconductor device according to claim 10, wherein said cell contact comprises at least one step (A) at end portion connected to said bit contact, and said bit contact is assembled so as to be electrically connected to at least one portion.

13. A method of manufacturing a semiconductor device in which a bit line electrically connected to a transistor is formed on an upper layer of said transistor formed on a semiconductor substrate comprising steps of:
(a) forming a transistor on the semiconductor substrate;
(b) forming a first interlayer insulation film covering said transistor,
(c) forming a cell contact electrically connected to said transistor in said first interlayer insulation film,
(d) forming a second interlayer insulation film covering said first interlayer insulation film and said cell contact,
(e) etching at least one selected from a group of said cell contact, first interlayer insulation film and said second interlayer insulation film in perpendicular direction of said semiconductor substrate,
(f) forming a bit contact comprising a portion electrically connected in parallel direction with said semiconductor substrate, and a portion electrically connected to said semiconductor substrate in perpendicular direction, with respect to said cell contact, and
(g) forming a bit line electrically connected to said bit contact.
